(19) United States
(12) Patent Application Publication
(10) Pub. No.: US 2010/0227461 A1
(43) Pub. Date: Sep. 9, 2010

(54) METHOD FOR THE FABRICATION OF SEMICONDUCTOR INTEGRATED CIRCUIT DEVICE

(75) Inventor: Hironori Ochi, Tokyo (JP)

Correspondence Address: MILES & STOCKBRIDGE PC, 1751 PINNACLE DRIVE, SUITE 500, MCLEAN, VA, 22102-3833, US

(73) Assignee: RENESAS TECHNOLOGY CORP.

(21) Appl. No.: 12/714,487

(22) Filed: Feb. 27, 2010

(30) Foreign Application Priority Data
Mar. 5, 2009 (JP) 2009-051666

(51) Int. Cl. H01L 21/30; H01L 21/28

(52) U.S. Cl. 438/586; 438/585; 257/E21.19; 257/E21.211

(57) ABSTRACT

In fabrication processes of semiconductor integrated circuit devices, a technique for improving the carrier mobility has been frequently employed. This technique utilizes strain caused by the stress typically of a silicon nitride film. With this, a batchwise wet processing with hot phosphoric acid should be performed so as to highly selectively remove the silicon nitride film over a complicated device structure on a front side of a wafer. This processing removes also a silicon nitride film on the back side of the wafer, and after a series of strain-imparting processes, a polysilicon member is exposed from the back side surface of the wafer. However, common techniques for cleaning typically of back sides of wafers may not sufficiently effectively clean the back side containing a polysilicon as a main component, because these techniques are designed to be adopted to a back side containing, for example, a silicon nitride film, but the polysilicon and the silicon nitride film differ from each other in properties. To void the problem, a wet cleaning process is performed before a lithography process. The wet cleaning process includes two steps, in which FPM cleaning and SPM cleaning are performed in this order.

### CROSS-REFERENCE TO RELATED APPLICATIONS

The disclosure of Japanese Patent Application No. 2009-51666 filed on Mar. 5, 2009 including the specification, drawings and abstract is incorporated herein by reference in its entirety.

### BACKGROUND OF THE INVENTION

The present invention relates to a technique that is effectively adopted so as to prevent heavy metal in fabrication methods for semiconductor integrated circuit devices (or semiconductor devices).

Japanese Unexamined Patent Publication No. 2001-110766 or the corresponding U.S. Pat. No. 6,592,677 discloses a technique of carrying out a back-side cleaning of a silicon-based wafer after copper plating in a process for forming an embedded copper wiring. According to this technique, hydrophilicity is imparted to the back side of the wafer by cleaning the back side with a hydrofluoric acid-hydrogen peroxide aqueous solution (FPM) to remove a silicon oxide film together with contaminated metals such as copper from the back side, thereafter further cleaning the back side with a sulfuric acid-hydrogen peroxide aqueous solution (SPM), and thereafter forming a silicon oxide film over the cleaned side.

Japanese Unexamined Patent Publication No. 2002-158207 discloses a technique for regenerating a silicon-based wafer having a copper film attached thereto. In this technique, the wafer is cleaned with a SPM, thereafter cleaned with a FPM, and thereafter further cleaned with a SPM.

Japanese Unexamined Patent Publication No. 2000-269178 or the corresponding US Unexamined Patent Publication No. 2004-053508 discloses a technique for preventing cross contamination from the process of forming an embedded copper wiring. In this technique, for example, a back side of a silicon-based wafer is cleaned typically with a SPM and/or a FPM.

Japanese Unexamined Patent Publication No. 2002-176022 discloses a technique for preventing cross contamination from the process of forming an embedded copper wiring. In this technique, for example, a back side of a silicon-based wafer is cleaned typically with an aqueous solution containing sulfuric acid, hydrogen peroxide, and hydrofluoric acid.

Japanese Unexamined Patent Publication No. 2006-148149 or the corresponding U.S. Pat. No. 6,586,161 discloses a technique for preventing cross contamination from the process of forming an embedded copper wiring. In this technique, for example, a back side of a silicon-based wafer is cleaned typically with sulfuric acid or nitric acid.

### SUMMARY OF THE INVENTION

In production processes of semiconductor integrated circuit devices, a technique for improving the carrier mobility has been employed more and more. This technique utilizes strain caused by the stress typically of a silicon nitride film. With this, a batchwise wet processing with hot phosphoric acid should be carried out so as to highly selectively remove the silicon nitride film arranged over a complicated device structure on a front side (device side) of a wafer.

The batchwise wet processing removes also the silicon nitride film on the back side of the wafer. After a series of processes for imparting strain, a polysilicon member or members (including amorphous silicon) as a main component configures the back side surface of the wafer.

Of processes for fabricating products of 45-nm technology node, fine-dimensional (microprocessing) lithography processes are performed typically in a gate electrode patterning step and a contact hole forming step in the front end of line (FEOL) and in a via and trench forming step in the back end of line (BEOL). The microprocessing lithography process includes a series of steps such as of resist film formation, light exposure, and development and need the use of an immersion type exposure apparatus. The immersion type exposure apparatus is very expensive, and it may be difficult to provide individual immersion type exposure apparatus for individual steps. Typically, there may occur the case where a wafer belonging to a front-end process passes through the same immersion type exposure apparatus before or after another wafer belonging to a back-end process passes therethrough. This may cause cross contamination typically from the back side of the previously passing wafer.

However, common techniques for the cleaning typically of back sides of wafers may not sufficiently effectively clean the above-mentioned back side containing a polysilicon as a main component. This is because these techniques (including techniques for automatically cleaning a back side of a wafer upon the cleaning of a front side (device side) of the wafer) are designed assuming that the back side contains, for example, a silicon nitride film or a silicon oxide film, but the polysilicon and these films differ from each other in properties.

The problem of insufficient cleaning may also occur even in a fabrication process in which a film such as a silicon nitride film remains on a back side of a product wafer. This is because the fabrication process currently often employs a single-wafer processing apparatus, and in this case, the back-side silicon nitride film is formed thinner so as to be used in the single-wafer processing apparatus, and such a thin back-side silicon nitride film may be partially lost during part of the back-end processes.

Further, the problem of insufficient cleaning may occur not only in the immersion type exposure apparatus but also in an extreme ultraviolet (EUV) exposure apparatus used in processes for the fabrication of products of 32-nm and 22-nm technology nodes.

The present invention has been made to solve these problems.

Accordingly, an object of the present invention is to provide a process for fabricating a semiconductor integrated circuit device with high reliability.

Other and further objects, novel features, and advantages of the present invention will be apparent from the following description with reference to the attached drawings.

A representative embodiment of the present invention as disclosed herein will be simply illustrated below.

Specifically, in a method for fabricating a semiconductor integrated circuit device, according to an embodiment of the present invention, a wet cleaning process of a back side of a wafer is performed. The wet cleaning process includes the following two steps and is performed before a lithography step during a wiring process in which a silicon member is exposed from the back side of the wafer.

The two steps are the steps of: (1) carrying out the first wet cleaning with a first aqueous solution containing hydrogen fluoride and hydrogen peroxide as principal solute components; and (2) after the step (1), carrying out the first wet cleaning with a second aqueous solution containing sulfuric acid and hydrogen peroxide as principal solute components.

Advantages obtained according to the representative embodiment of the present invention will be simply illustrated below.

Specifically, the wet cleaning process of the wafer back side herein includes the two steps of carrying out a FPM process and carrying out a SPM process in this order and is performed before the lithography step. The wet cleaning process thereby remarkably reduces the heavy metal contaminants level of the wafer back side and prevents cross contamination through the lithography step.

### BRIEF DESCRIPTION OF THE DRAWINGS

FIG. 1 is a process block flow chart showing a wafer process and a back-side cleaning process included in the wafer process, in a method for fabricating a semiconductor integrated circuit device (as a product including embedded copper wirings) according to an embodiment of the present invention;

FIG. 2 is a process block flow chart showing, in detail, the back-side cleaning process in the wafer process in the method for fabricating a semiconductor integrated circuit device (as a product including embedded copper wirings) according to an embodiment of the present invention;

FIG. 3 is a general top view of a cleaning apparatus for use in a back-side cleaning process performed in the wafer process of the method for fabricating a semiconductor integrated circuit device (as a product including an embedded copper wiring) according to the embodiment of the present invention;

FIG. 4 is a cross-sectional side view of the cleaning apparatus shown in FIG. 3, showing a structure in the vicinity of a spin table of the apparatus;

FIG. 5 is a sectional view of a principal part of the device, as a part of a flow chart of the wafer process (gate electrode patterning) in the method for fabricating a semiconductor integrated circuit device (as a product including embedded copper wirings) according to an embodiment of the present invention;

FIG. 6 is a sectional view of a principal part of the device, as a part of the flow chart of the wafer process (formation of side walls and other parts) in the method for fabricating a semiconductor integrated circuit device (as a product including embedded copper wirings) according to an embodiment of the present invention;

FIG. 7 is a sectional view of a principal part of the device, as a part of the flow chart of the wafer process (formation of a strain-imparting film) in the method for fabricating a semiconductor integrated circuit device (as a product including embedded copper wirings) according to an embodiment of the present invention;

FIG. 8 is a sectional view of a principal part of the device, as a part of the flow chart of the wafer process (selective etching of the strain-imparting film) in the method for fabricating a semiconductor integrated circuit device (as a product including embedded copper wirings) according to an embodiment of the present invention;

FIG. 9 is a sectional view of a principal part of the device, as a part of the flow chart of the wafer process (removal of a resist used in the selective etching of the strain-imparting film) in the method for fabricating a semiconductor integrated circuit device (as a product including embedded copper wirings) according to an embodiment of the present invention;

FIG. 10 is a sectional view of a principal part of the device, as a part of the flow chart of the wafer process (removal of the entire strain-imparting film) in the method for fabricating a semiconductor integrated circuit device (as a product including embedded copper wirings) according to an embodiment of the present invention;

FIG. 11 is a sectional view of a principal part of the device, as a part of the flow chart of the wafer process (removal of a silicon oxide film for protecting a gate electrode structure) in the method for fabricating a semiconductor integrated circuit device (as a product including embedded copper wirings) according to an embodiment of the present invention;

FIG. 12 is a sectional view of a principal part of the device, as a part of the flow chart of the wafer process (formation of a silicide) in the method for fabricating a semiconductor integrated circuit device (as a product including embedded copper wirings) according to an embodiment of the present invention;

FIG. 13 is a sectional view of a principal part of the device, as a part of the flow chart of the wafer process (formation of a silicon nitride film for a self-aligned contact (SAC) process) in the method for fabricating a semiconductor integrated circuit device (as a product including embedded copper wirings) according to an embodiment of the present invention;

FIG. 14 is a sectional view of a principal part of the device, as a part of the flow chart of the wafer process (opening of a contact hole) in the method for fabricating a semiconductor integrated circuit device (as a product including embedded copper wirings) according to an embodiment of the present invention;

FIG. 15 is a sectional view of a principal part of the device, as a part of the flow chart of the wafer process (formation of an interlayer insulating film (interlayer dielectric film) of a second embedded wiring layer) in the method for fabricating a semiconductor integrated circuit device (as a product including embedded copper wirings) according to an embodiment of the present invention;

FIG. 16 is a sectional view of a principal part of the device, as a part of the flow chart of the wafer process (opening of a via hole of the second embedded wiring layer) in the method for fabricating a semiconductor integrated circuit device (as a product including embedded copper wirings) according to an embodiment of the present invention;

FIG. 17 is a sectional view of a principal part of the device, as a part of the flow chart of the wafer process (patterning of a resist film for trench processing of the second embedded wiring layer) in the method for fabricating a semiconductor integrated circuit device (as a product including embedded copper wirings) according to an embodiment of the present invention;

FIG. 18 is a sectional view of a principal part of the device, as a part of the flow chart of the wafer process (formation of trenches of the second embedded wiring layer) in the method for fabricating a semiconductor integrated circuit device (as a product including embedded copper wirings) according to an embodiment of the present invention;

FIG. 19 is a sectional view of a principal part of the device, as a part of the flow chart of the wafer process (removal of an etch stop film of the second embedded wiring layer) in the method for fabricating a semiconductor integrated circuit device (as a product including embedded copper wirings) according to an embodiment of the present invention;

FIG. 20 is a sectional view of a principal part of the device, as a part of the flow chart of the wafer process (embedding of a copper wiring in the second embedded wiring layer) in the method for fabricating a semiconductor integrated circuit device (as a product including embedded copper wirings) according to an embodiment of the present invention;

FIG. 21 is a sectional view of a principal part of the device, as a part of the flow chart of the wafer process (opening of a pad) in the method for fabricating a semiconductor integrated circuit device (as a product including embedded copper wirings) according to an embodiment of the present invention; and

FIG. 22 is a graph for the comparison of data between a common back-side cleaning process and the back-side cleaning process employed in the wafer process of the method for fabricating a semiconductor integrated circuit device (as a product including embedded copper wirings) according to an embodiment of the present invention.

### DETAILED DESCRIPTION OF THE PREFERRED EMBODIMENTS

### Summary of Some Embodiments

Initially, representative embodiments of the present invention will be briefly illustrated below.

1. A method for fabricating a semiconductor integrated circuit device, comprising the steps of: (a) forming a second insulating film over a first insulating film over a device side of a wafer, the second insulating film to be an interlayer insulating film for an embedded wiring (for a buried interconnection); (b) after the step (a), carrying out a first wet cleaning of a back side of the wafer; (c) after the step (b), introducing the wafer into a first lithographic apparatus and carrying out a patterning of a first resist film; and (d) after the step (c), carrying out a first processing of the second insulating film by a first dry etching on the device side of the wafer in the presence of the patterned first resist film, in which the step (b) includes the substeps of: (b1) carrying out the first wet cleaning with a first aqueous solution containing hydrogen fluoride and hydrogen peroxide as principal solute components; and (b2) after the substep (b1), carrying out the first wet cleaning with a second aqueous solution containing sulfuric acid and hydrogen peroxide as principal solute components.

2. The method for fabricating a semiconductor integrated circuit device, according to Item 1 above, may further comprise the steps of: (e) after the step (d), removing the first resist film; (f) after the step (e), carrying out a second wet cleaning of the back side of the wafer; (g) after the step (f), introducing the wafer into the first lithographic apparatus or a second lithographic apparatus and carrying out a patterning of a second resist film; (h) after the step (g), carrying out a second processing of the second insulating film by a second dry etching on the device side of the wafer in the presence of the patterned second resist film, in which the step (f) includes the substeps of: (f1) carrying out the second wet cleaning with a third aqueous solution containing hydrogen fluoride and hydrogen peroxide as principal solute components; and (f2) after the substep (f1), carrying out the second wet cleaning with a fourth aqueous solution containing sulfuric acid and hydrogen peroxide as principal solute components.

3. In the method for fabricating a semiconductor integrated circuit device, according to one of Items 1 and 2 above, the first processing may be via etching for the embedded wiring.

4. In the method for fabricating a semiconductor integrated circuit device, according to one of Items 2 and 3 above, the second processing may be trench etching for the embedded wiring.

5. In the method for fabricating a semiconductor integrated circuit device, according to any one of Items 1 to 4 above, the embedded wiring may be a copper-based dual damascene wiring.

6. In the method for fabricating a semiconductor integrated circuit device, according to any one of Items 1 to 5 above, the first wet cleaning may be carried out as a single-wafer processing.

7. In the method for fabricating a semiconductor integrated circuit device, according to any one of Items 1 to 5 above, the second wet cleaning may be carried out as a single-wafer processing.

8. In the method for fabricating a semiconductor integrated circuit device, according to any one of Items 1 to 7 above, the steps (a), (b), (c), and (d) may be carried out substantially in the absence of a silicon nitride insulating film over the back side of the wafer.

9. In the method for fabricating a semiconductor integrated circuit device, according to any one of Items 1 to 7 above, the steps (e), (f), (g), and (h) may be carried out substantially in the absence of a silicon nitride insulating film over the back side of the wafer.

10. In the method for fabricating a semiconductor integrated circuit device, according to any one of Items 1 to 9 above, the first aqueous solution may be a hydrofluoric acid-hydrogen peroxide aqueous solution (FPM) and the second aqueous solution is a sulfuric acid-hydrogen peroxide aqueous solution (SPM).

11. In the method for fabricating a semiconductor integrated circuit device, according to any one of Items 1 to 10 above, the third aqueous solution may be a FPM and the fourth aqueous solution may be a SPM.

12. In the method for fabricating a semiconductor integrated circuit device, according to any one of Items 1 to 11 above, each of the first aqueous solution and the second aqueous solution is preferably supplied at normal temperatures to the back side of the wafer.

13. In the method for fabricating a semiconductor integrated circuit device, according to any one of Items 1 to 12 above, each of the third aqueous solution and the fourth aqueous solution is preferably supplied at normal temperatures to the back side of the wafer.

14. In the method for fabricating a semiconductor integrated circuit device, according to any one of Items 1 to 13 above, the step of forming the second insulating film may be carried out as a single-wafer processing.

15. In the method for fabricating a semiconductor integrated circuit device, according to any one of Items 1 to 14 above, the semiconductor integrated circuit device may include a metal insulator semiconductor field-effect transistor (MISFET), and the method for fabricating a semiconductor integrated circuit device further comprises the step of (i) before the step (a) and after the step of patterning a gate electrode of the MISFET, carrying out a batchwise wet processing of the wafer with hot phosphoric acid.

16. A method for fabricating a semiconductor integrated circuit device, comprising the steps of: (a) forming a thin film over an insulating film over a device side of a wafer, the thin film being used for the formation of a metal wiring; (b) after the step (a), caring out a wet cleaning of a back side of the wafer; (c) after the step (b), introducing the wafer into a lithographic apparatus and carrying out a patterning of a resist film; and (d) after the step (c), caring out a processing of the thin film by dry etching of the device side of the wafer in the presence of the patterned resist film, in which the step (b) includes the substeps of: (b1) carrying out the wet cleaning using a first aqueous solution containing hydrogen fluoride and hydrogen peroxide as principal solute components; and (b2) after the substep (b1), carrying out the wet cleaning using a second aqueous solution containing sulfuric acid and hydrogen peroxide as principal solute components.

17. In the method for fabricating a semiconductor integrated circuit device, according to Item 16 above, the first wet cleaning may be carried out as a single-wafer processing.

18. In the method for fabricating a semiconductor integrated circuit device, according to Item 16 or 17 above, the second wet cleaning may be carried out as a single-wafer processing.

19. In the method for fabricating a semiconductor integrated circuit device, according to one of Items 16 and 18 above, the steps (a), (b), (c), and (d) may be carried out substantially in the absence of a silicon nitride insulating film over the back side of the wafer.

20. In the method for fabricating a semiconductor integrated circuit device, according to any one of Items 16 to 19 above, the first aqueous solution may be a FPM and the second aqueous solution may be a SPM.

21. In the method for fabricating a semiconductor integrated circuit device, according to any one of Items 16 to 20 above, each of the first aqueous solution and the second aqueous solution is preferably supplied at normal temperatures to the back side of the wafer.

22. In the method for fabricating a semiconductor integrated circuit device, according to any one of Items 16 to 21 above, the step of forming the thin film may be carried out as a single-wafer processing.

23. In the method for fabricating a semiconductor integrated circuit device, according to any one of Items 16 to 22 above, the semiconductor integrated circuit device may include a MISFET, and the method for fabricating a semiconductor integrated circuit device further comprises the step of (i) before the step (a) and after the step of patterning a gate electrode of the MISFET, carrying out a batchwise wet processing of the wafer with hot phosphoric acid.

[Description Format, Basic Terms, and Usage]

1. An embodiment of the present invention may be described dividedly into plural sections where required for the sake of convenience, but unless otherwise specified, it is to be understood that the divided sections are not independent of each other, but respective portions of a single example, or in a relation such that one is a partial detail of the other or is a modification of part or the whole of the other. As to similar portions, repetition thereof is omitted in principle. Components in an embodiment are not essential unless otherwise specified, unless they are limited theoretically to specified numbers thereof, and unless they are clearly essential contextually.

As used herein the term “semiconductor integrated circuit device” mainly refers to a semiconductor chip (such as a single crystal silicon substrate) over which transistors (active devices) as main components, and other components such as resistors and capacitors are integrated. Representative examples of transistors include metal insulator semiconductor field effect transistors (MISFETs) represented by metal oxide semiconductor field effect transistors (MOSFETs). Representative examples of integrated circuit structures include complementary metal insulator semiconductors (CMISs) represented by complementary metal oxide semiconductors (CMOSs) in which N-channel MISFETs and P-channel MISFETs are used in combination.

Processes included in a wafer process of current semiconductor integrated circuit devices, namely, large-scale integrated circuits (LSIs), are generally roughly classified as front-end-of-line (FEOL) processes and back-end-of-line (BEOL) processes. The FEOL processes typically include processes from loading of raw material silicon wafers to, approximately, a premetal process. The premetal process includes the formation (deposition) of an interlayer insulating film and other components between a gate electrode structure and a lower end of an M1 wiring layer, the formation of contact holes, plugging with tungsten, and embedding. The BEOL processes include processes from the formation of the M1 wiring layer to, approximately, the formation of a pad opening in a final passivation film over an aluminum pad electrode. When a wafer-level packaging process is performed, this process is also included in the BEOL processes. Of the FEOL processes, processes such as the gate electrode patterning process and contact hole forming process are microprocessing processes that need particularly fine processing (microprocessing). Of the BEOL processes, via and trench forming processes particularly in local wirings of relatively lower layers especially need microprocessing. Specifically, the “local wirings of relatively lower layers” refer to, for example, embedded fine wirings of from M1 to approximately M3 in embedded wirings including about four layers; and refer to embedded fine wirings of from M1 to approximately M5 in embedded wirings including about ten layers. As used herein the symbol “MN”, wherein N is from 1 to about 15, refers to a N-th wiring as counted from the bottom. For example, M1 refers to a first wiring, and M3 refers to a third wiring.

2. Likewise, in the description typically of embodiments, the phrase “X comprising (or containing or including) A” typically about material or component does not exclude selection of any other element than A as one of principal components, unless otherwise specified, and unless otherwise indicated contextually. For example, as to a component, the above phrase means, for example, “X containing A as a principal component”. Typically, it is apparent that for example, the term “a silicon member” is not limited to pure silicon, and may include multicomponent alloy containing SiGe alloy or other silicon materials as a principal component, and a member containing other components such as additives. Likewise, it is also apparent that the terms such as “silicon oxide film” and “silicon oxide insulating film” include not only a film including relatively pure undoped silicon dioxide; but also a thermally-oxidized film including fluorosilicate glass (FSG), TEOS-based silicon oxide, silicon oxycarbide (SiOC), or carbon-doped silicon oxide, or organosilicate glass (OSG), phosphorus silicate glass (PSG), or borophosphosilicate glass (BPSG); a chemical vapor deposition (CVD) oxide film; a coating type silicon oxide film typically including spin on glass (SOG) or nano-clustering silica (NSC); a silica-based low-k insulating film (porous insulating film) including the same member as described above but having pores; and a composite film containing the above-mentioned material as a principal component, with another silicon-based insulating film.

In addition to silicon oxide insulating films, silicon nitride insulating films are commonly used as silicon-based insulating films in semiconductors. Exemplary materials for such silicon nitride insulating films include SiN, SiCN, SiNH, and SiCNH. As used herein the term “silicon nitride” means and includes both SiN and SiNH, unless otherwise specified. Likewise, the term “SiCN” as used herein means and includes both SiCN and SiCNH.

In this connection, SiC (silicon carbide) has properties analogous to those of SiN, whereas SiON (silicon oxynitride) has properties generally analogous to those of silicon oxide and a film thereof is often classified as a silicon oxide insulating film.

Silicon nitride films are widely used as etch stop films (etching stopper films) in a self-aligned contrast technique (SAC) and are also used as stress-imparting films in a stress memorization technique (SMT).

Likewise, the term “nickel silicide” generally refers to nickel monosilicide but includes not only relatively pure nickel monosilicide but also an alloy, mixed crystal, or another substance that mainly contains nickel monosilicide as a principal component. Exemplary silicides for use herein are not limited to nickel silicides but also include established silicides such as cobalt silicide, titanium silicide, and tungsten silicide. In addition to nickel (Ni) films, exemplary metal films to be silicidized include nickel alloy films such as Ni—Pt alloy films (films of alloys containing nickel and platinum (Pt)), Ni—V alloy films (films of alloys containing nickel and vanadium (V)), Ni—Pd alloy films (films of alloys containing nickel and palladium (Pd)), Ni—Yb alloy films (films of alloys containing nickel and ytterbium (Yb)), and Ni—Er alloy film (films of alloys containing nickel and erbium (Er)). These silicides containing nickel as a principal metal element are generically referred to as “nickel-based silicide (s)”.

3. Likewise, it is apparent that preferred examples typically of figures or shapes, positions, and properties are described in the embodiments, but the present invention is not strictly limited thereto, unless otherwise specified, and unless contextually otherwise indicated.

4. Further, when referring to a specific value or quantity, there may be a value exceeding the specific value, or may be a value less than the specific value unless otherwise specified, unless the number of components is theoretically limited, and unless contextually otherwise indicated.

5. The term “wafer” generally refers to a single crystal silicon wafer over which semiconductor integrated circuit devices (the same goes for semiconductor devices, and electronic devices) are formed, but may include a composite wafer containing an insulating substrate and a semiconductor layer or another component, such as an epitaxial wafer, a semiconductor-on-insulator (SOI) substrate, or a liquid crystal display (LCD) glass substrate.

6. As used herein the term “lithographic apparatus” refers to an apparatus for semiconductor fabrication, which has at least an exposure apparatus and which may have a related inspection system. Under general conditions, the lithographic apparatus is an integrated apparatus and has units such as a unit for the coating (to carry out, for example, coating and prebaking) typically of a resist; an exposure unit; and a development unit (to carry out, for example, development and post-baking).

7. With respect to a metal wiring layer typically of an embedded wiring, the term “interlayer insulating film” means and includes both an interlayer insulating film in a narrow sense and an intralayer insulating film.

8. The term “stress memorization technique (SMT)” refers to a technique for improving the channel mobility of a carrier so as to improve properties of a transistor. In this technique, the stress of a stress-imparting film, such as a silicon nitride film, is stored in a channel or a member in the vicinity thereof (stress memorization member) typically of an MISFET. The memorization is achieved by controlling the timing typically of a heat treatment. Such stress memorization techniques are classified as a variety of techniques typically by the selection of the stress memorization member. A stress memorization technique illustrated below is a technique using the property that a gate polysilicon member (a polysilicon portion in a gate electrode in a final product) memorizes a stress when it turns from an amorphous state into polysilicon in a narrow sense. It is apparent, however, that a technique for use herein is not especially limited thereto.

9. Cleaning solutions (cleaners) or chemical solutions for use herein will be described below. The composition of such a chemical solution is indicated by volume ratio, i.e., percent by volume, unless otherwise specified.

(1) DHF: A dilute hydrofluoric acid (DHF) is a diluted hydrofluoric acid generally having a concentration of from 0.5% to 10%. The DHF is relatively highly capable of removing regular metallic impurities but is poorly capable of removing copper and other substances having low ionization tendencies. FPM as mentioned below is a mixture of DHF with hydrogen peroxide working as an oxidizing agent and is thereby more highly capable of removing copper than DHF is.

(2) FPM: An FPM (the abbreviation of a hydrogen fluoride-hydrogen peroxide mixture) as the first aqueous solution or the third aqueous solution is a hydrofluoric acid-hydrogen peroxide aqueous solution (an aqueous solution containing hydrogen fluoride and hydrogen peroxide as principal solute components). FPM does not etch, for example, a polysilicon but etches a silicon oxide film. Therefore it is considered to be capable of removing copper contaminants even when contained in a native oxide film or chemical oxide film (hereinafter each of these silicon oxide films is referred to as a “surface layer oxide film”) within several nanometers depth in a surface layer of a back side of a wafer. FPM can be used at normal temperatures and is thereby suitable for single-wafer processing. A representative regular composition of FPM is such that the ratio among hydrogen fluoride (HF):hydrogen peroxide (H₂O₂) :water (H₂O) is about 1:1:100. An optimal preferred range of the ratio is from about 0.2:0.5:100 to about 1:1:50, and a practically preferred range thereof is from about 0.1:0.2:100 to about 1:1:5. It should be noted, however, the ratio can take another range than above. In the composition, it is not desirable to set the concentration of HF (hydrogen fluoride) so high with respect to the representative composition, because such a concentrated HF may excessively etch a film such as silicon nitride film of the front side of the wafer. In contrast, the concentration of H₂O₂ is speculated to be considerably freely set but is limited in view of cost.

Additives in relatively trace amounts or those having weak activities are generally allowed to be contained in FPM, but nitric acid and analogous substances are not desirable, because they etch a polysilicon or another silicon member and may thereby cause particles.

Exemplary possible alternate chemical solutions for FPM include an aqueous mixed solution containing about 1% or less of DHF in ozonated water.

(3) SPM: A sulfuric acid-hydrogen peroxide mixture (SPM) as the second aqueous solution or the fourth aqueous solution is a sulfuric acid-hydrogen peroxide aqueous solution (an aqueous solution containing sulfuric acid and hydrogen peroxide as principal solute components). Utilizing very strong oxidation activity of peroxysulfuric acid (Caro's acid), SPM is generally used for the removal of organic contaminants, but it also has relatively high capability of removing metal contaminants (capability of removing copper) as with HPM. SPM does not substantially etch the polysilicon member and thereby does not cause particles, because it includes substantially no etchant against a silicon oxide film, such as hydrofluoric acid. SPM is usable at normal temperatures and is suitable for single-wafer processing. High viscosity of sulfuric acid is generally undesirable for the cleaning of a front side (device side) of a wafer which bears a fine pattern, but the back-side cleaning is free from this problem. An usual representative composition is such that the ratio among sulfuric acid (H₂SO₄):H₂O₂:H₂O is about 1:3.3:47.7. An optimal range of the ratio may be from about 0.5:1:50 to about 5:10:50, and a practical range thereof may be from about 0.2:0.5:50 to about 10:10:50. It should be noted, however, the ratio can take another range than above.

Additives in relatively trace amounts or those having weak activities are generally allowed in SPM, but hydrofluoric acid and other silicon oxide etchant are undesirable under regular conditions.

Exemplary possible alternate chemical solutions for FPM include a hydrochloric acid-hydrogen peroxide mixture (HPM) and an aqueous solution containing sulfuric acid as a principal solute component. The HPM may generally have a compositional ratio of HCl:H₂O₂:H₂O ranging from about 1:1:500 to about 1:1:5.

(4) APM: An ammonium hydrogen-hydrogen peroxide mixture (APM) is also called “Standard Clean/1 (SC-1)”, is one of principal chemical solutions used in so-called RCA cleaning, and is used mainly for the removal of organic contaminants. APM is somewhat disadvantageous in single-wafer cleaning, because it is mainly used at relatively high temperatures of from 80° C. to 90° C. A regular representative composition of APM is such that the ratio among NH₄OH:H₂O₂:H₂O is around 1:1:5. APM generally has a pH of from about 10 to about 12.

(5) HPM: A hydrogen chloride-hydrogen peroxide mixture (HPM) is also called “Standard Clean 2 (SC-2)”, is one of principal chemical solutions for use in RCA cleaning, and is mainly used for the removal of metal contaminants. HPM is somewhat disadvantageous in single-wafer cleaning, because it is mainly used at relatively high temperatures of from 80° C. to 90° C. A regular representative composition of HPM is such that the ratio among HCl:H₂O₂:H₂O is around 1:1:5. HPM has a pH of generally from about 0 to about 2.

(6) BHF: A buffered HF (BHF) is a buffered hydrofluoric acid and is generally a mixed solution of hydrofluoric acid (HF) and ammonium fluoride (NH₄F) and may further contain additives such as surfactants. A representative volume ratio of hydrofluoric acid to ammonium fluoride (HF:NH₄F) is about 1:7. BHF is generally used for the etching of a silicon oxide film in microprocessing.

(7) Ozonated water: An ozonated water is generally prepared by dissolving ozone gas at around a use point in pure water to a concentration on the order of parts per million (ppm). Because of its strong oxidizing activity, the ozonated water can be used in the present invention as an alternate chemical solution for SPM. The ozonated water has advantages such that it is usable at normal temperatures and needs very low running costs.

### FURTHER DETAILED DESCRIPTION OF THE PREFERRED EMBODIMENTS

The preferred embodiments will be illustrated below in further detail. In each drawing, the same or similar part is designated by the same or similar reference symbol or numeral, and a description thereof will not be repeated in principle.

In the attached drawings, hatching and other indications may be omitted even in cross-sectional views, for the sake of brevity, or when it is apparently distinguishable from a cavity or space. In this connection, a background borderline may be omitted even when the object is a two-dimensionally closed hole typically when apparent from the description.

The details of the stress memorization technique (SMT) can be found in Japanese Patent Application No. 2008-128113 (filed in Japan on May 15, 2008), and the description relating these is not repeated herein in principle.

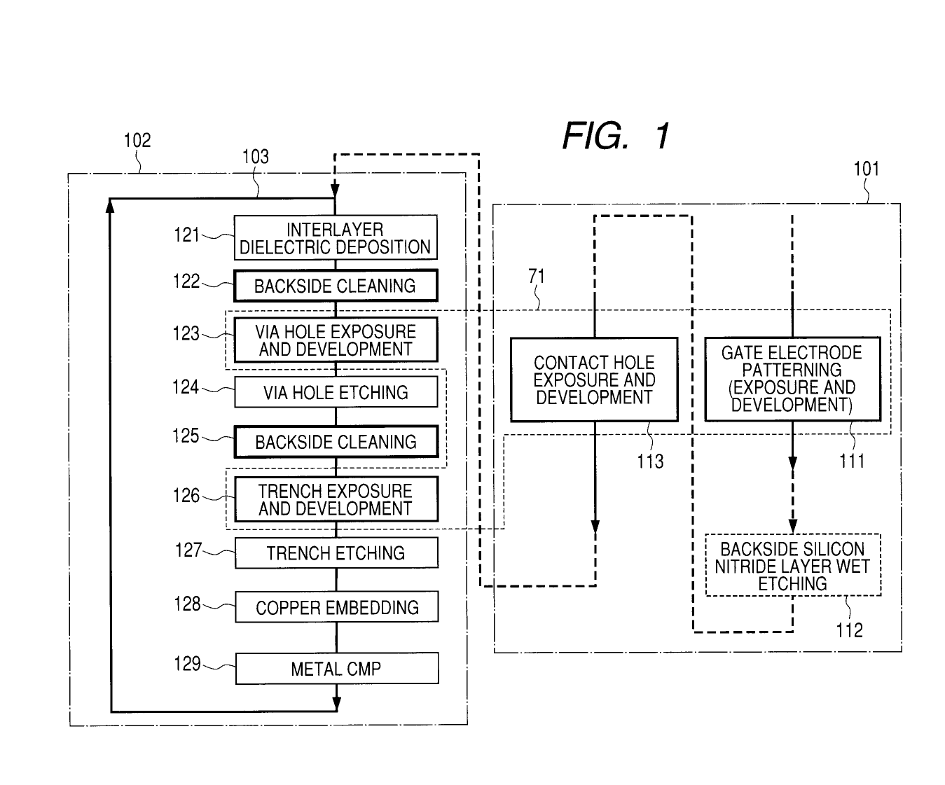

1. Explanation of a wafer process and a back-side cleaning process included therein in a method for fabricating a semiconductor integrated circuit device (as a product including embedded copper wirings) according to an embodiment of the present invention (with reference mainly to FIG. 1)

An embodiment of the present invention will be illustrated below. In the following, a system-on-chip (SOC) product having a CMIS integrated circuit structure of 45 nm technology node will be illustrated as an example. Initially, the overall flow of the wafer process and how the back-side cleaning is performed therein will be explained with reference to FIG. 1.

As illustrated in FIG. 1, steps (processes) included in a wafer process for the fabrication of a semiconductor integrated circuit are roughly classified as two groups, i.e., back-end-of-line (BEOL) processes 102, and front-end-of-line (FEOL) processes 101 performed prior to the BEOL processes 102. Hereinafter, a copper damascene wiring as a representative example of embedded metal wirings will be described as an example of a wiring process. Details of each step or process included in the BEOL process will be illustrated below in Section 3. The back-end repeating processes (BEOL processes) 102 include an embedded wiring process loop 103 repeated on each of a plurality of wiring layers. Of steps included in the embedded wiring process loop 103, a via hole exposure/development step (via hole lithographic process) 123 and a trench exposure/development step (trench lithographic process) 126 belong to lithographic processes in accordance with design rules and require microprocessing. Of steps included in the front-end-of-line processes 101, steps such as a coating/exposure/development step 111 for the pattering of a gate electrode and a coating/exposure/development step 113 for the forming of a contact hole belong to lithographic processes in accordance with design rules and require microprocessing. These lithographic processes in accordance with the design roles need a microprocessing lithographic apparatus (first lithographic apparatus) 71, such as a scanning projection exposure apparatus for immersion lithography for the application of ArF excimer laser light (homogeneous ultraviolet rays at a wavelength of 193 nm). Such lithographic apparatuses are very expensive.

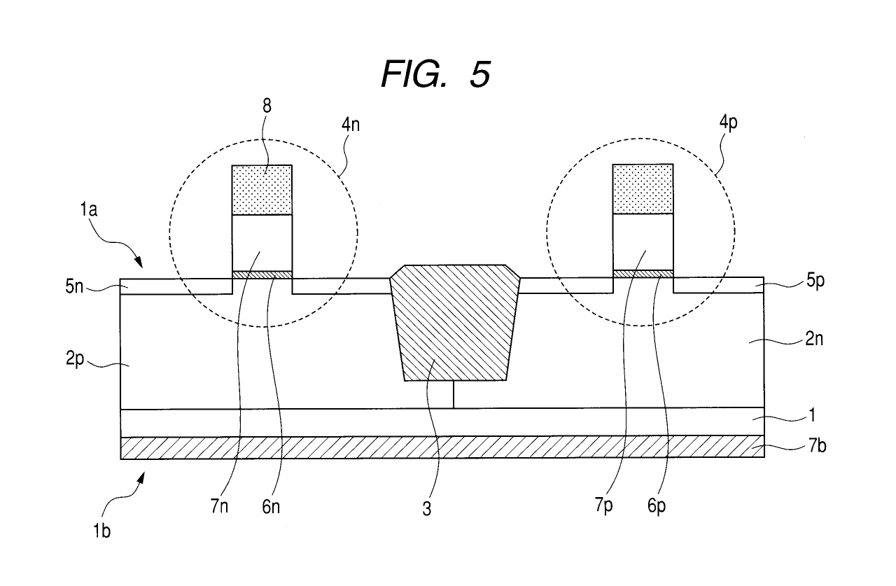

A variety of processes according to the stress memorization technique (SMT) are expected to be adopted to CMIS integration technologies of 45 nm technology node or later, for the purpose of improving operating speeds of devices. In these SMT processes, a strain-imparting film with high stress, represented by a silicon nitride film, is deposited over a gate electrode structure. Thus, a channel region whose properties are to be improved is allowed to memorize the stress. In this connection, the strain-imparting film such as silicon nitride film is deposited by batchwise chemical vapor deposition (batchwise CVD) and is thereby deposited also over the back side in general. After the strain memorization, the entire removal of the silicon nitride film (see FIG. 10) over a device side (first principal plane) la of a wafer 1 (see FIG. 5) is needed, and this is performed by batchwise wet etching (a wet etching step 112 of back side silicon nitride film in FIG. 1) using hot phosphoric acid having a high selective ratio. As a result of this process, however, the silicon nitride film over a back side (second principal plane) 1b of the wafer 1 is also entirely removed, because the entire wafer 1 is immersed in a chemical solution. Specifically, only a polysilicon film is exposed from (present in) the back side 1b of the wafer 1 after the wet etching step 112. The polysilicon film has been deposited over the back side 1b simultaneously with the deposition of a polysilicon film for the formation of the gate electrode (see FIG. 5). In a current cutting-edge process line, the back side 1b of the wafer 1 remains substantially as intact (bearing the polysilicon film alone) in subsequent steps up to a final step of the wafer process, because steps or processes downstream from this step (wet etching step 112) are mainly performed by single-wafer-processing CVD.

So, there may occur the case where a wafer in one of the front-end processes 101 and another wafer in one of the back end repeating processes 102 are processed in the same microprocessing lithographic apparatus (first lithographic apparatus) 71. This may cause the transfer of heavy metal contaminants such as copper between the wafers in the two processes, i.e., cross contamination of the heavy metals.

As a first countermeasure to avoid the carry-in of contaminants into the microprocessing lithographic apparatus 71, back-side cleaning steps 122 and 125 are effectively performed. Specifically, the back-side cleaning steps 122 and 125 are cleaning steps to remove heavy metals from the back side 1b of the wafer 1. These steps are performed before the microprocessing lithography processes in the embedded wiring process loop 103, i.e., before the via hole lithography step 123 and before the trench lithography step 126, respectively. In other words, the back-side cleaning steps are performed before the wafer is introduced into the microprocessing lithographic apparatus 71.

The back-side cleaning is expected to be effective when adopted to the steps in question (namely, the via hole lithography step 123 and the trench lithography step 126) in at least one of a plurality of embedded wiring process loops 103. The back-side cleaning can substantially completely avoid the cross contamination when adopted to the steps in question in substantially all the embedded wiring process loops 103. Independently, the back-side cleaning is expected to be effective even when adopted to at least one of the steps in question in one loop. The back-side cleaning can further completely avoid the cross contamination when adopted to substantially all the steps in question. Regarding the phrase “before the wafer is introduced into the microprocessing lithographic apparatus 71”, the back-side cleaning is preferably performed immediately before the wafer is introduced into the microprocessing lithographic apparatus 71. As used herein the term “immediately before” refers to that the back-side cleaning step and the lithography step are so close to each other that there is no other contamination source between the two steps. Accordingly, the presence of one or more other steps between the two steps is not excluded.

Next, as a second countermeasure, it is effective to adopt a cleaning process optimized with respect to the back side 1b of the wafer 1, which back side 1b contains a polysilicon as a principal component (the phrase “back side 1b contains a polysilicon as a principal component” means that one having a native oxide film with a thickness of about several nanometers is also included). This is because known wafer back-side cleaning techniques are designed on the assumption that an insulating film such as silicon nitride film or silicon oxide film is present in the back side 1b, but do not consider a back side 1b containing a polysilicon film as a principal component as herein. Though effective even when employed alone, the second countermeasure more effectively prevents the cross contamination when employed in combination with the first countermeasure.

In this embodiment, the back-side cleaning steps 122 and 125 are performed on the wafer 1 to be processed, after an interlayer film formation step 121 (including, for example, cap film formation) and after the resist removal which is performed after a via hole etching step 124 (see FIG. 1).

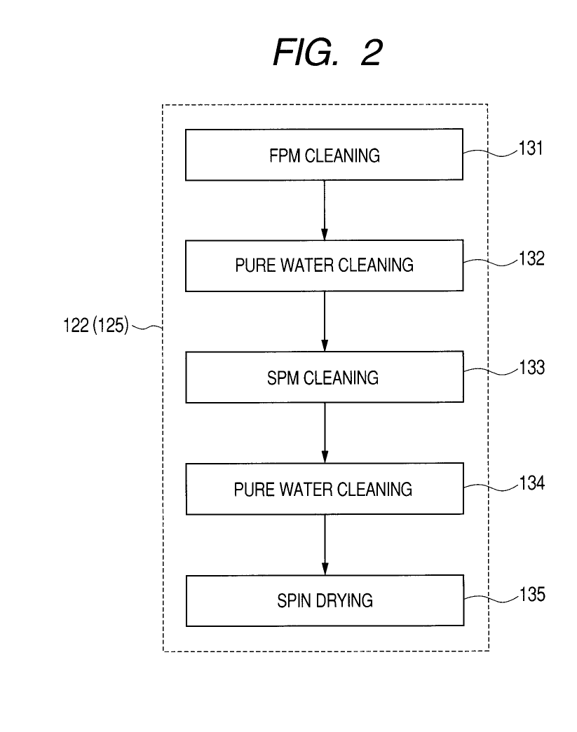

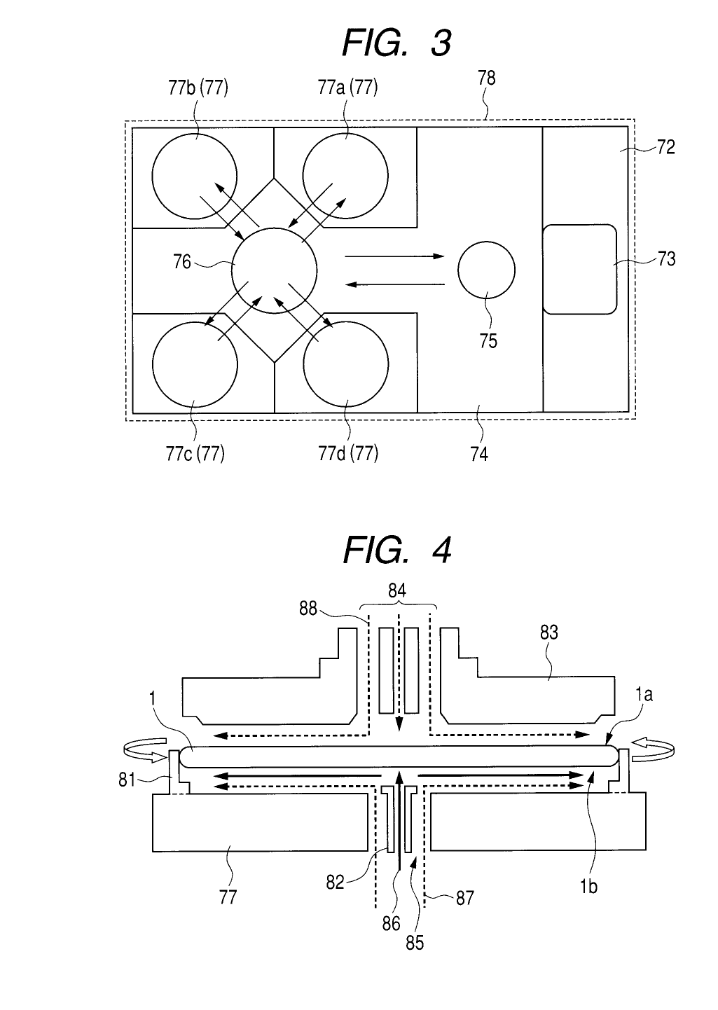

2. Explanation of a cleaning apparatus for use in the back-side cleaning processes in the wafer process of the method for fabricating a semiconductor integrated circuit device (as a product including embedded copper wirings) according to an embodiment of the present invention (with reference mainly to FIG. 2, FIG. 3, and FIG. 4)

The wafer back-side cleaning steps 122 and 125 will be illustrated in detail with reference to FIGS. 2, 3, and 4.

With reference to FIG. 3, the wafer 1 to be processed is loaded typically in a front opening unified pod (FOUP) (wafer carrier) 73 and the FOUP 73 is set in a load port 72 of a back-side cleaning apparatus 78. The back-side cleaning apparatus 78 may be a stand-alone apparatus but may also be an apparatus integrated typically with a resist stripper. Next, the wafer is introduced from the FOUP 73 into an intermediate chamber 74 in the apparatus by the action of a wafer transfer robot 75 for the transfer between the load port and the intermediate chamber and is delivered to a wafer transfer robot 76 for the transfer between the intermediate chamber and cleaning tables. Thereafter, the wafer 1 is set on any one of the cleaning tables (spin tables) 77a, 77b, 77c, and 77d (77) by the action of the wafer transfer robot 76 for the transfer between the intermediate chamber and cleaning tables (see FIG. 4). The wafer 1 is set so that the device side 1a faces upward.

The structure and operation in the vicinity of the spin table 77, and the flow of the back-side cleaning process will be described with reference to FIG. 2 and FIG. 4. As illustrated in FIG. 4, the wafer 1 is held by a plurality (in general three or four) of wafer holding chuck pins (wafer holding mechanisms) 81 provided on the top of the spin table 77.

The wafer 1 and the spin table 77 under this condition begin to rotate and thereafter maintain a constant rotational speed typically of about 1500 rpm. Independently, an atmosphere blocking plate 83 is provided over the wafer 1 so as to face the device side 1a of the wafer 1. The atmosphere blocking plate 83 rotates in the same direction at the same speed as the rotation of the spin table 77.

With the rotation, initially, nitrogen gas streams 87 and 88 for blocking the atmosphere begin to be supplied from a lower gas nozzle 85 and an upper gas nozzle 84, respectively. Thereafter, a chemical solution or cleaning liquid (including pure water) 86 begins to be supplied. The supply time of the cleaning liquid, i.e., the cleaning process time is typically about 40 seconds. The cleaning liquid in this process is an FPM, namely, an aqueous solution containing hydrofluoric acid and hydrogen peroxide as principal solute components. The cleaning liquid is supplied at normal temperatures, generally at around 25° C. This step is an FPM cleaning step 131 in FIG. 2. Each cleaning liquid here and hereinafter is supplied as a mixture prepared beforehand.

Thereafter, the cleaning liquid 86 is changed over to pure water while other conditions remain as intact (i.e., the supply of the nitrogen gas streams 87 and 88 is continued; hereinafter the same). Virtually simultaneously with the changeover of the cleaning liquid to the pure water, the rotational speed is reduced to a rotational speed typically of from about 1000 to about 1200 rpm, and this rotational speed is maintained. The cleaning process time is typically about 15 seconds. The cleaning liquid is supplied at normal temperatures, generally at around 25° C. This step is a pure water cleaning (pure water rinsing) step 132 in FIG. 2.

Next, the cleaning liquid 86 is changed over to an SPM, i.e., an aqueous solution containing sulfuric acid and hydrogen peroxide as principal solute components while other conditions remain as intact. Virtually simultaneously with the changeover of the cleaning liquid, the rotational speed is increased again to a rotational speed typically of about 1500 rpm, and this rotational speed is maintained. The cleaning process time is typically about 20 seconds. The cleaning liquid is supplied at normal temperatures, generally at around 25° C. This step is an SPM cleaning step 133 in FIG. 2.

Next, while other conditions remain as intact, the cleaning liquid 86 is changed over to pure water. Virtually simultaneously with the changeover of the cleaning liquid, the rotational speed is reduced to a rotational speed typically of from about 200 to about 1200 rpm, and this rotational speed is maintained. The cleaning process time is typically about 30 seconds. The cleaning liquid is supplied at normal temperatures, generally at around 25° C. This step is a pure water cleaning (pure water rinsing) step 134 in FIG. 2.

Next, while other conditions remain as intact (the nitrogen gas streams 87 and 88 are continuously supplied), the supply of the cleaning liquid 86 is stopped. Virtually simultaneously with this, the rotational speed is raised typically to about 2500 rpm, and this rotational speed is maintained. The time to maintain this rotational speed, i.e., drying time is typically about 30 seconds. This step is a spin drying step 135 in FIG. 2.

Thereafter, the rotation is stopped, and simultaneously with this, the supply of the nitrogen gas streams 87 and 88 is stopped. Subsequent to this, the processed wafer 1 is recovered into the intermediate chamber 74 by the action of the wafer transfer robot 76 for the transfer between the cleaning table and the intermediate chamber. The wafer 1 is thereafter delivered to the wafer transfer robot 75 for the transfer between the intermediate chamber and the load port and is returned to the FOUP 73 by the action of the wafer transfer robot 75. Thus, the back-side cleaning process is completed.

Though not essential, the washing or rinsing with water is generally preferably performed between cleaning steps with chemical solutions so as to prevent interference between the chemical solutions. The washing or rinsing with water may be omitted when a chemical solution used in a later step (subsequent step) also acts typically as a rinsing liquid. This may lead to shortage of the process time. The addition of any additional step between the steps shown in FIG. 2 is not excluded. The explanation herein is made by taking an example where the steps in FIG. 2 are each performed over the same spin table 77; but a series of the steps may be performed over different spin tables. However, the steps are preferably performed over the same spin table 77 for the sake of shortening the process time.

3. Explanation of sectional views of a principal part of the device, as parts of the flow chart of the wafer process in the method for fabricating a semiconductor integrated circuit device (as a product including embedded copper wirings) according to an embodiment of the present invention (with reference mainly to FIG. 1 and FIGS. 5 to 11)

Hereinafter will be explained, for example, the sectional views of a principal part of the device, as parts of the flow chart of the wafer process in the method for fabricating a semiconductor integrated circuit device (as a product including embedded copper wirings) according to an embodiment of the present invention. Initially, the cross-sectional structure of the device at the time when the gate electrode patterning is completed will be explained with reference to FIG. 5.

As illustrated in FIG. 5, CMIS type integrated circuit devices are generally formed over a device side 1a (a first principal plane; or an opposite side to a back side 1b) of a wafer 1. The wafer 1 herein is generally a single-crystal P type silicon-based wafer having relatively low impurity concentrations. The wafer may have any size not limited and may be, for example, a 300-mm wafer, a 200-mm wafer, a 450-mm wafer, or a wafer of another size; and where necessary, the wafer (substrate) may be a substrate of another type, such as an N type semiconductor substrate, an epitaxial substrate, or an SOI substrate. In the formation of a CMIS type integrated circuit device, specifically, a P type well region 2p and an N type well region 2n are formed on the device side 1a of the wafer 1; and a shallow trench isolation (STI) insulating film 3 for isolation between devices is arranged between the P type well region 2p and the N type well region 2n over the surface of the silicon substrate (wafer) 1. An N-channel MISFET 4n and a P-channel MISFET 4p are provided in the vicinities of the surfaces of the P type well region 2p and of the N type well region 2n, respectively. An N type low-concentration source or drain region (N-type extension region) 5n of the N-channel MISFET 4n is provided over the surface of the P type well region 2p; and a P type low-concentration source or drain region (P-type extension region) 5p of the P-channel MISFET 4p is provided over the surface of the N type well region 2n. These N-channel MISFET 4n and P-channel MISFET 4p have components such as gate insulating films 6n and 6p and gate electrodes 7n and 7p, respectively. At this point of time, a back-side polysilicon film 7b is present on the back side 1b of the wafer 1. The back-side polysilicon film 7b has been deposited simultaneously with the deposition of gate polysilicon films 7n and 7p through batchwise CVD. The back-side polysilicon film 7b has a thickness typically of about 70 nm.

Next, a device forming process will be simply illustrated sequentially from the patterning of gate electrodes. With reference to FIG. 5, the wafer 1 after the completion of back-side cleaning is introduced into a microprocessing lithographic apparatus 71 (first lithographic apparatus) or another microprocessing lithographic apparatus (second lithographic apparatus). A polysilicon film, for example, is formed over substantially the whole surface of the device side 1a of the wafer 1, and a negative-working photoresist film typically for the exposure of ArF laser light is formed thereover in a resist coating unit of the apparatus. Thereafter a gate electrode pattern provided in a mask is transferred typically through step-and-scan exposure in an immersion exposure unit of the apparatus. Development and other processes are thereafter performed in a development unit of the apparatus (e.g., the microprocessing lithographic apparatus 71) to thereby form a resist film 8 for gate electrode patterning as illustrated in FIG. 5. The wafer 1 is thereafter discharged out of the apparatus (e.g., the microprocessing lithographic apparatus 71) (coating/exposure/development step 111 for gate electrode patterning in FIG. 1). The above illustrated example is an example where the microprocessing lithographic apparatus 71 includes a coating unit, an exposure unit, and a development unit. However, it is also acceptable that each of or one of these units is provided as an independent apparatus.

The polysilicon film is thereafter dry-etched using, as a mask, the resist film 8 for gate electrode patterning, to form gate electrodes 7n and 7p as illustrated in FIG. 5. The resist film 8 for gate electrode patterning, which is no longer needed, is thereafter fully removed typically through ashing.

Subsequently, the device side 1a of the wafer 1 over the P type well region 2p and one over the N type well region 2n are alternately covered with a resist film, and ion injection is performed to form an N type low-concentration source or drain region 5n and a P type low-concentration source or drain region 5p over the surfaces of the respective regions.

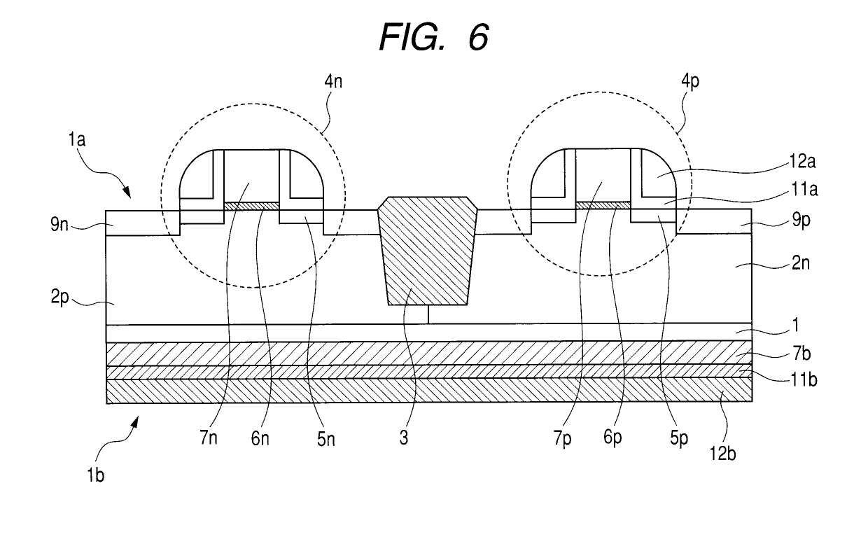

Next, as illustrated in FIG. 6, a relatively thin offset insulating film (silicon nitride film) 11a is deposited over substantially the whole surface of the device side 1a of the wafer 1 through batchwise CVD. In this process, a back-side silicon nitride film 11b corresponding to the offset insulating film 11a is also deposited. Next, anisotropic dry etching of the device side 1a is performed to thereby pattern a pair of L-shaped offset insulating films 11a. Subsequently, a side-wall spacer insulating film (silicon nitride film) 12a is deposited over substantially the whole surface of the device side 1a of the wafer 1 through batchwise CVD. The side-wall spacer insulating film (silicon nitride film) 12a has a thickness larger than that of the offset insulating films 11a. In this process, a back-side silicon nitride film 12b corresponding to the side-wall spacer insulating film is also deposited. Next, anisotropic dry etching of the device side 1a is performed to thereby pattern the side-wall spacer insulating film 12a.

Subsequently, the device side 1a of the wafer 1 over the P type well region 2p and one over the N type well region 2n are alternately covered with a resist film, and ion injection is performed to form an N type high-concentration source or drain region 9n and a P type high-concentration source or drain region 9p over the surfaces of the respective regions.

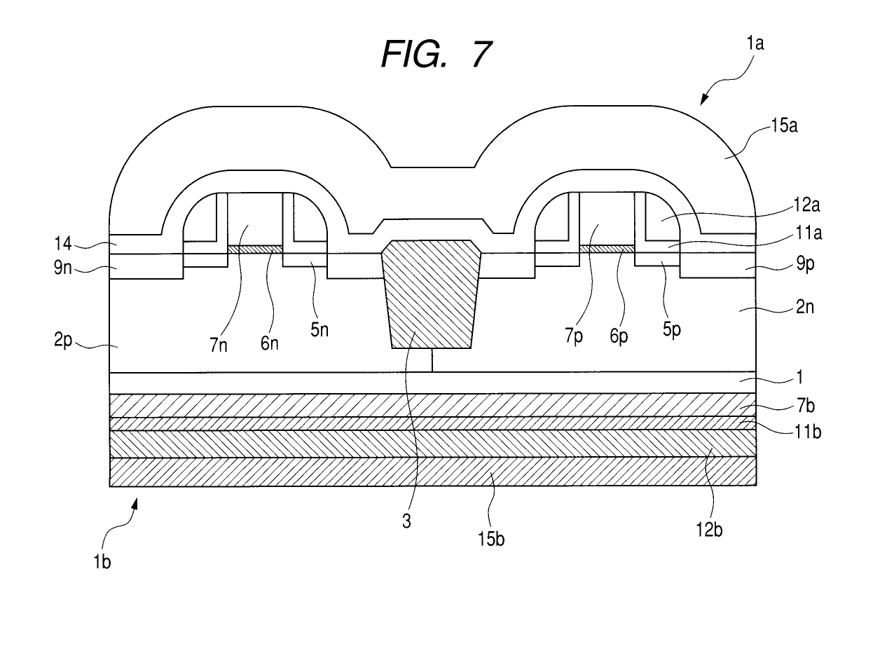

Next, as illustrated in FIG. 7, a silicon oxide cap insulating film 14 (silicon oxide film for protecting the gate electrode structure) is deposited over substantially the whole surface of the device side 1a of the wafer 1 typically through plasma CVD according to single-wafer processing. In addition, a silicon nitride film 15a for stress imparting is deposited over substantially the whole surface of the silicon oxide cap insulating film 14 on the device side 1a of the wafer 1 typically through batchwise CVD. The thickness of the silicon nitride film 15a is typically about 35 nm. The thickness ranges preferably from about 20 to about 50 nm. The stress-imparting silicon nitride film 15a is a film having a tensile stress, whose intensity preferably ranges, for example, from about 0.3 to about 1.7 GPa. The stress-imparting silicon nitride film 15a in this example is provided in order to improve the carrier (electron) mobility of the N-channel MISFET 4n. In contrast, in order to improve the carrier (hole) mobility of the P-channel MISFET 4p, a stress-imparting silicon nitride film for imparting a compressive stress is to be deposited. It is widely known that the tensile stress, compressive stress, or the intensity thereof can be freely controlled by adjusting the conditions for plasma CVD film deposition.

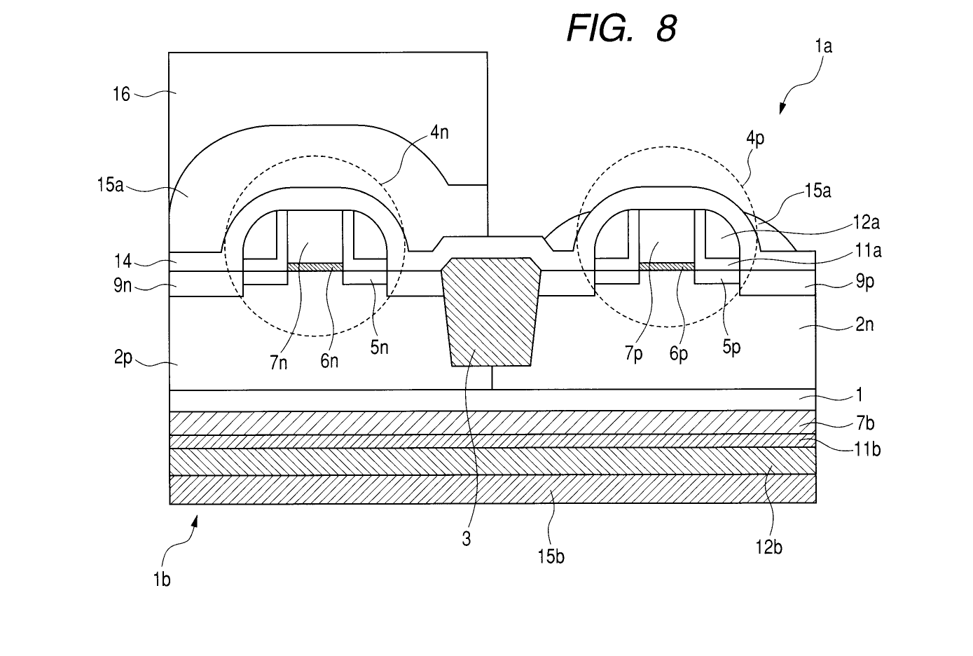

Next, as illustrated in FIG. 8, anisotropic dry etching of the device side 1a of the wafer 1 is performed while a portion over the P type well region 2p is covered by a resist film 16 for the selective etching of the stress-imparting silicon nitride film. Thus, the stress-imparting silicon nitride film 15a in a portion where the resist film 16 is absent is substantially fully removed, except for a part in the vicinity of the side-wall spacer insulating film 12a of the P-channel MISFET 4p.

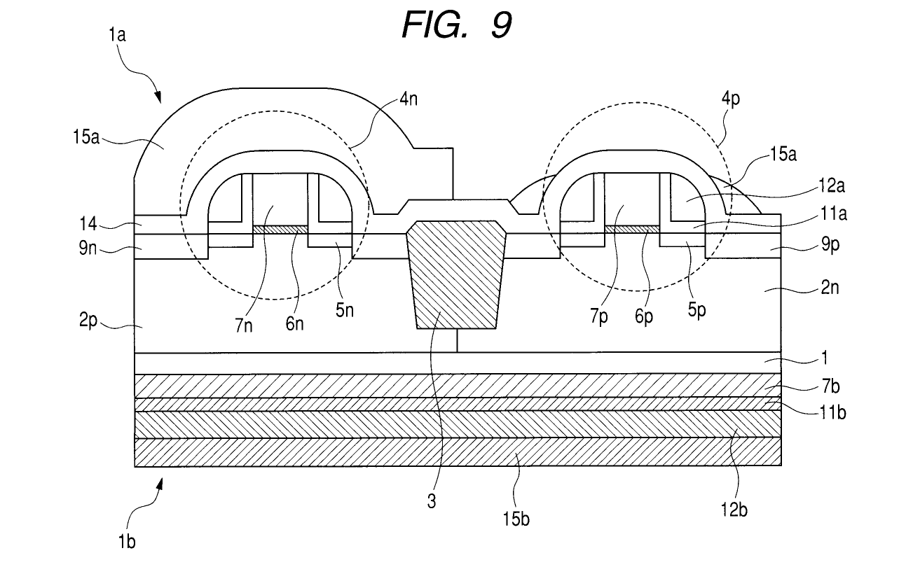

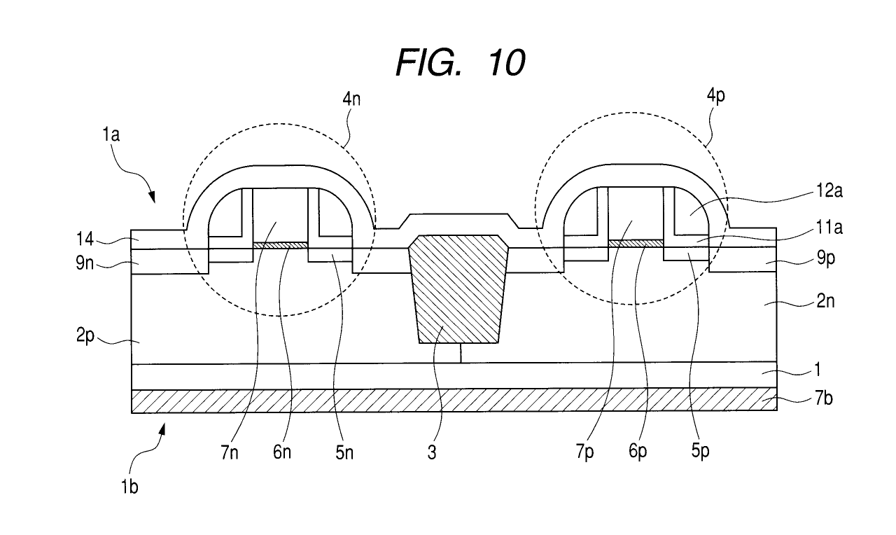

Next, as illustrated in FIG. 9, the resist film 16, which is no longer needed, is fully removed typically through ashing. Subsequently, an annealing process is performed so as to convert the gate electrodes 7n and 7p from amorphous silicon to polysilicon This annealing process can be, for example, a spike annealing process at temperatures of from about 950° C. to about 1150° C. Upon this annealing process, the N type low-concentration source or drain region 5n, P type low-concentration source or drain region 5p, N type high-concentration source or drain region 9n, and P type high-concentration source or drain region 9p are generally activated.

Next, as illustrated in FIG. 10, the stress-imparting silicon nitride film 15a over the front-side surface (device side) 1a of the wafer 1, as well as back-side silicon nitride film 15b corresponding to the stress-imparting silicon nitride film 15a, the back-side silicon nitride film 12b corresponding to the side-wall spacer insulating film 12a, and the back-side silicon nitride film 11b corresponding to the offset insulating film 11a are fully removed through a batchwise wet process with hot phosphoric acid. In this process, the temperature of the hot phosphoric acid is typically about 155° C. and the process time is typically about 10 minutes.

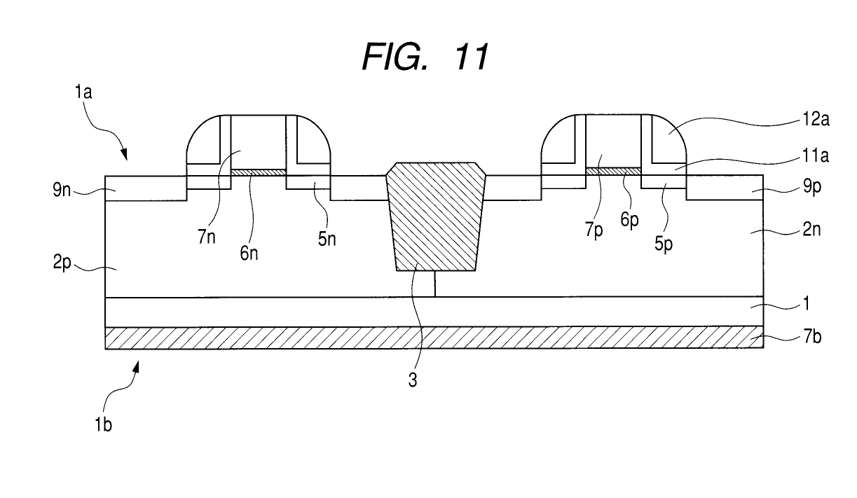

Next, as illustrated in FIG. 11, the silicon oxide film (gate cap film) 14 for protecting the gate electrode structure over the device side 1a of the wafer 1 is substantially fully removed with a hydrofluoric acid-based wet etchant. This wet etchant does not substantially etch the silicon nitride film and the polysilicon film. In this process, when there is a portion not to be silicidized typically in a peripheral circuit, the gate cap film is not removed in the portion so as to use as a mask in silicidization.

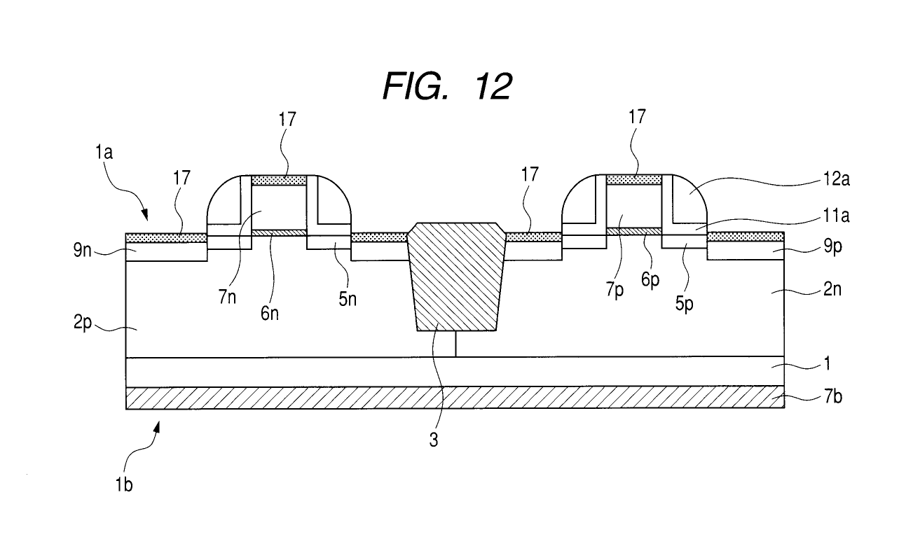

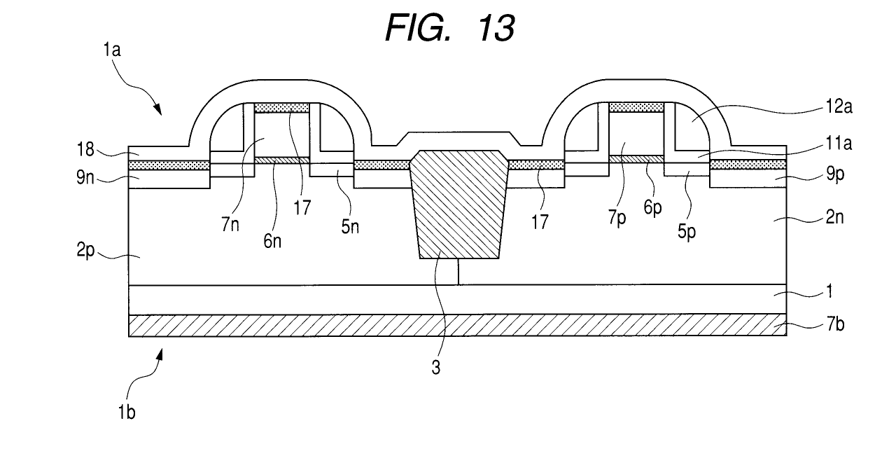

Next, as illustrated in FIG. 12, the surfaces of the N type high-concentration source or drain region 9n, the P type high-concentration source or drain region 9p, the gate electrode 7n of the N-channel MISFET, and the gate electrode 7p of the P-channel MISFET are each converted to, for example, a nickel-based silicide film 17.

Next, as illustrated in FIG. 13, a relatively thin silicon nitride film 18 for self-aligned contact (SAC) is deposited over substantially the whole surface of the device side 1a of the wafer 1 typically through single-wafer-processing CVD.

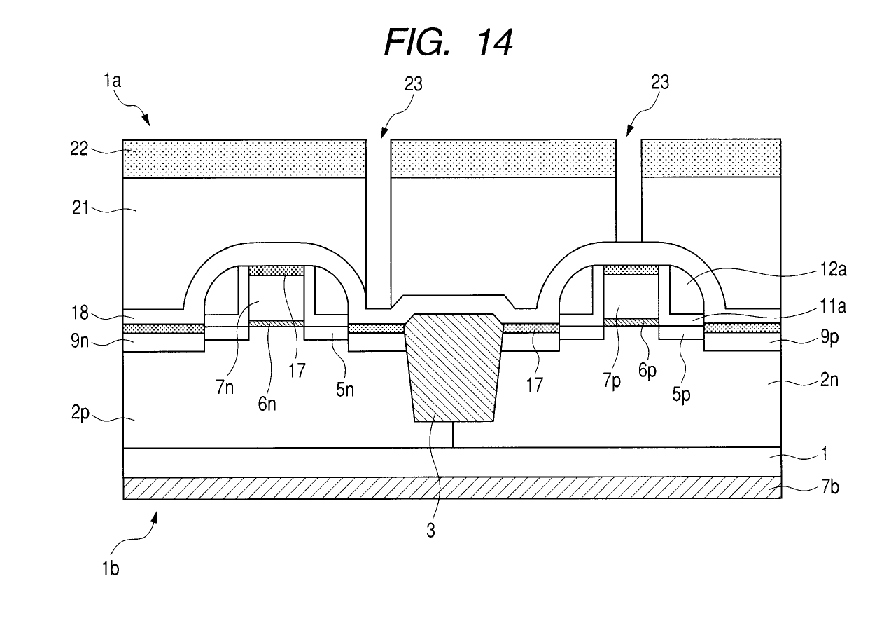

Next, as illustrated in FIG. 14, a pre-metal interlayer insulating film (silicon oxide film) 21, whose thickness is larger than that of the silicon nitride film 18, is deposited over the silicon nitride film 18 typically through single-wafer-processing plasma CVD. Further, the wafer 1 is introduced into the microprocessing lithographic apparatus 71 or another microprocessing lithographic apparatus (second lithographic apparatus). A positive-working photoresist film 22 typically for the formation of contact holes through ArF exposure is deposited over the pre-metal interlayer insulating film 21 of the device side 1a in a resist coating unit of the apparatus. Thereafter, a contact hole pattern of the mask is transferred typically through step-and-scan exposure in an immersion exposure unit of the apparatus. Processes such as development are thereafter performed in a development unit of the apparatus (e.g., the microprocessing lithographic apparatus 71) to form (pattern) a resist film 22 for the formation of contact holes. The wafer 1 is thereafter discharged out of the apparatus (e.g., microprocessing lithographic apparatus 71) (coating/exposure/development step 113 for the formation of contact holes in FIG. 1).

Further, as illustrated in FIG. 14, contact holes 23 reaching the top surface of the contact etch stop film 18 are opened through anisotropic dry etching using the patterned resist film 22 as a mask. In addition, the contact etch stop film 18 is etched through dry etching with another gas so as to allow the contact hole 23 to extend to the top surface of the underlying nickel-based silicide film. Thereafter the resist film 22, which is no longer needed, is fully removed typically through ashing.

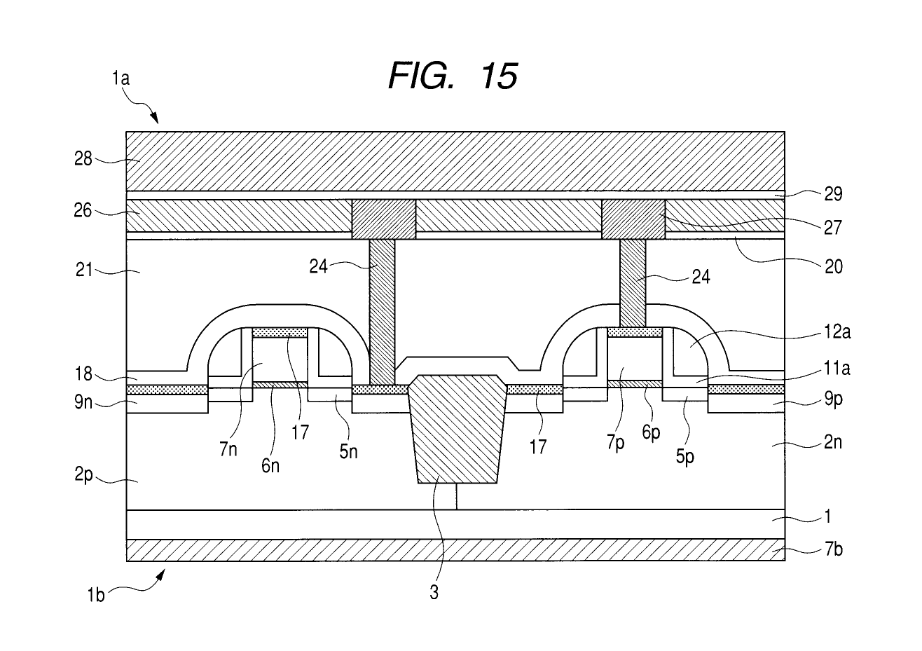

Next, as illustrated in FIG. 15, the contact holes 23 are each filled with a tungsten plug (tungsten plug in a contact portion) 24. This tungsten plug generally includes a thin film, such as a titanium nitride film, present in an under layer and periphery of the film, and a tungsten-based plug body as a principal part. Hereinafter this is also true typically for other tungsten plugs.

Further, as illustrated in FIG. 15, an etch stop film 20 and an interlayer insulating film 26 each for a first embedded wiring layer are each deposited over the pre-metal insulating film 21 typically through single-wafer-processing plasma CVD. The etch stop film 20 may for example be a silicon carbonitride film, i.e., a SiCN film but can be any other silicon nitride film. Hereinafter the same is true also for other etch stop films. The interlayer insulating film 26 may for example be a silicon oxide film such as a plasma enhanced tetramethylorthosilicate (plasma TEOS) film but can be any low-k silicon oxide insulating film such as a fluorosilicate glass (FSG) film or a silicon oxycarbide (SiOC) film. Independently, a regular silicon oxide film, such as a plasma TEOS film, may be laid as a cap film over the top surface of such a low-k silicon oxide insulating film. These are hereinafter also true for other interlayer insulating films. Within the etch stop film 20 and the interlayer insulating layer 26, a first embedded wiring (buried wiring) 27 (copper-based M1 damascene wiring) is embedded or buried with the interposition of a barrier metal film of the first embedded wiring layer. The barrier metal film may generally be a multilayer film including a tantalum nitride film and a tantalum film but can also be a film of a metal having a high melting point, such as ruthenium, or a multilayer film of the metal film with a film of its nitride. This is hereinafter also true for other barrier metal films. The embedding of copper is generally performed by forming a seed copper layer, and thereafter performing, for example, copper electroplating. This is hereinafter also true for the embedding of copper. The first embedded wiring layer is of a so-called single damascene structure.

Further, an etch stop film 29 and an interlayer insulating film 28 each for a second embedded wiring layer are deposited over the interlayer insulating film 26 of the first embedded wiring layer typically through single-wafer-processing plasma CVD (an interlayer insulating film forming step 121 in FIG. 1).

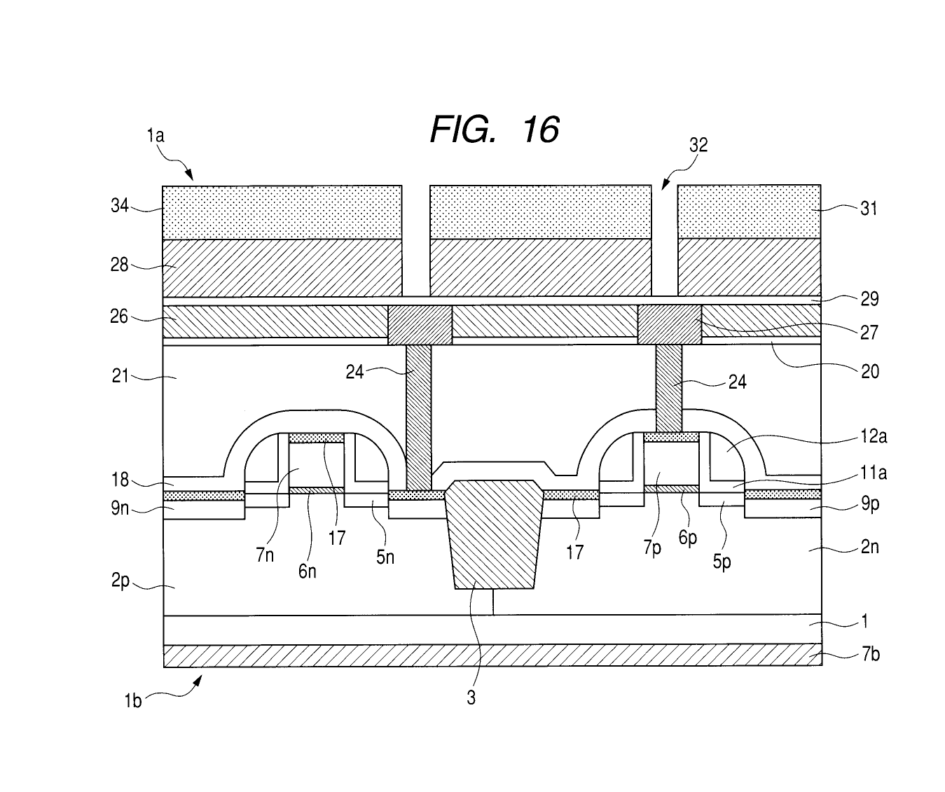

Next, a back-side cleaning process is performed (a back-side cleaning step 122 in FIG. 1), and, as illustrated in FIG. 16, the wafer 1 after the completion of the back-side cleaning process is introduced into the microprocessing lithographic apparatus 71 or another microprocessing lithographic apparatus, and a positive-working photoresist film 31 for the formation of via holes typically through ArF exposure is applied over the interlayer insulating film 28 on the device side 1a in a resist coating unit of the apparatus. Thereafter a via hole pattern of a mask is transferred typically through step-and-scan exposure in an immersion exposure unit of the apparatus. Processes such as development are thereafter performed in a development unit of the apparatus (e.g., the microprocessing lithographic apparatus 71) to thereby form (pattern) a resist film 31 for the formation of via holes. The wafer 1 is thereafter discharged out of the apparatus (e.g., the microprocessing lithographic apparatus 71) (a via hole exposure/development step or via hole lithography step 123 in FIG. 1).

Further, as illustrated in FIG. 16, via holes 32 reaching the top surface of the etch stop film 29 are initially opened through anisotropic dry etching using the patterned resist film 31 as a mask (a via hole etching step 124 in FIG. 1). Thereafter, the resist film, which is no longer needed, is fully removed typically through ashing.

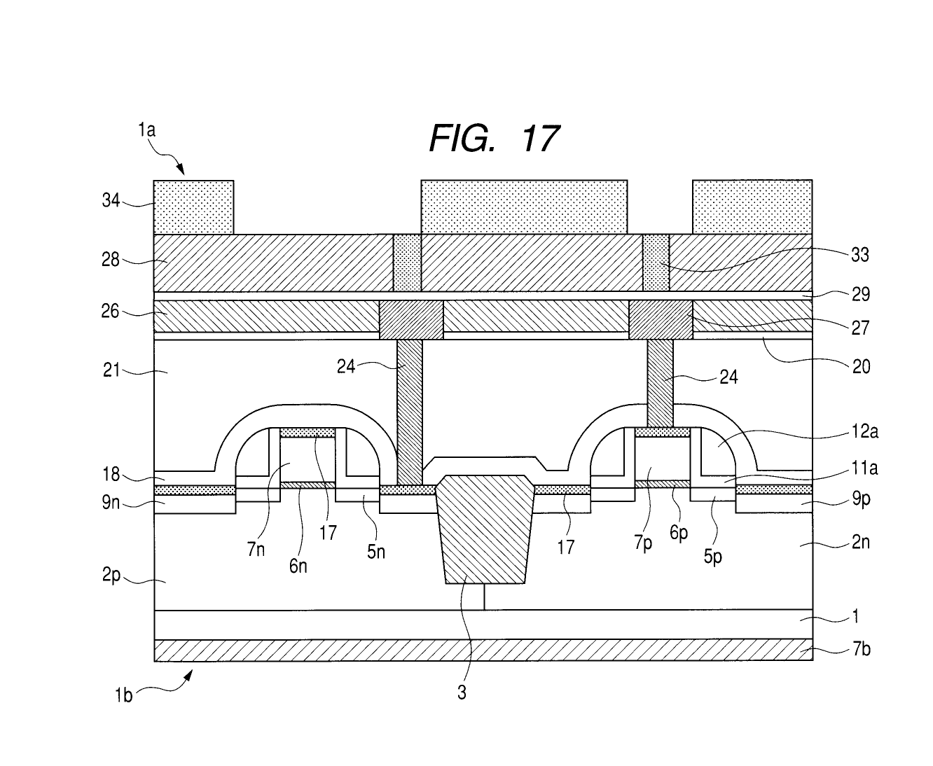

Next, a back-side cleaning process is performed (a back-side cleaning step 125 in FIG. 1), and, as illustrated in FIG. 17, the wafer 1 after the completion of the back-side cleaning process is introduced into the microprocessing lithographic apparatus 71 or another microprocessing lithographic apparatus. Initially, the via holes 32 are filled with a resist plug 33 typically through coating in a (resist) coating unit of the apparatus. Thereafter a positive-working photoresist film 34 for the formation of trenches typically through ArF exposure is applied over the interlayer insulating film 28 on the device side 1a. Thereafter a trench pattern of a mask is transferred typically through step-and-scan exposure in an immersion exposure unit of the apparatus. Processes such as development are thereafter performed in a development unit of the apparatus (e.g., the microprocessing lithographic apparatus 71) to thereby form (pattern) a resist film 34 for the formation of trenches. The wafer 1 is thereafter discharged out of the apparatus (e.g., the microprocessing lithographic apparatus 71) (a trench exposure/development step or trench lithography step 126 in FIG. 1).

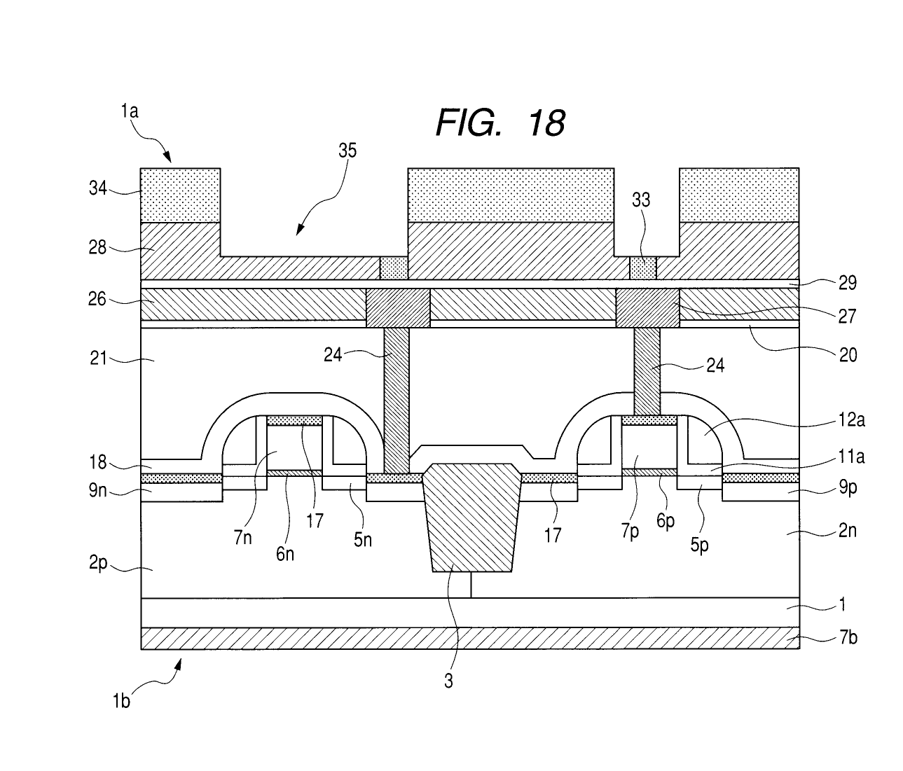

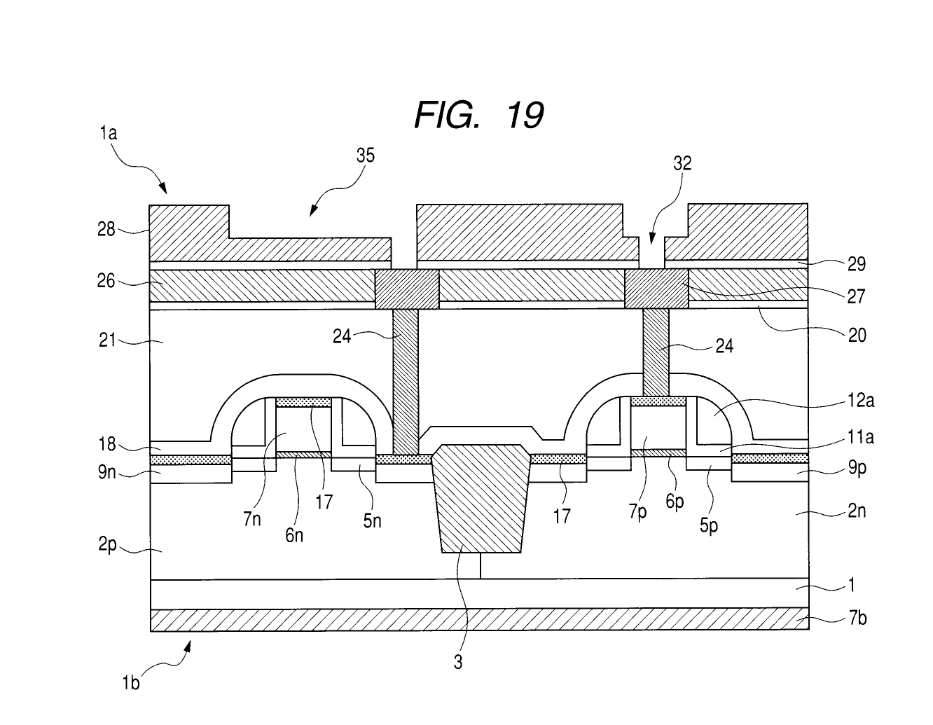

Next, as illustrated in FIG. 18, a trench (wiring trench) 35 is initially formed through anisotropic dry etching using the patterned resist film 34 as a mask (a trench etching step 127 in FIG. 1).

Next, as illustrated in FIG. 19, the resist film 34 and the resist plugs 33, which are no longer needed, are fully removed typically through ashing. Thereafter, the etch stop film 29 at the bottom of the via holes is removed typically through dry etching.

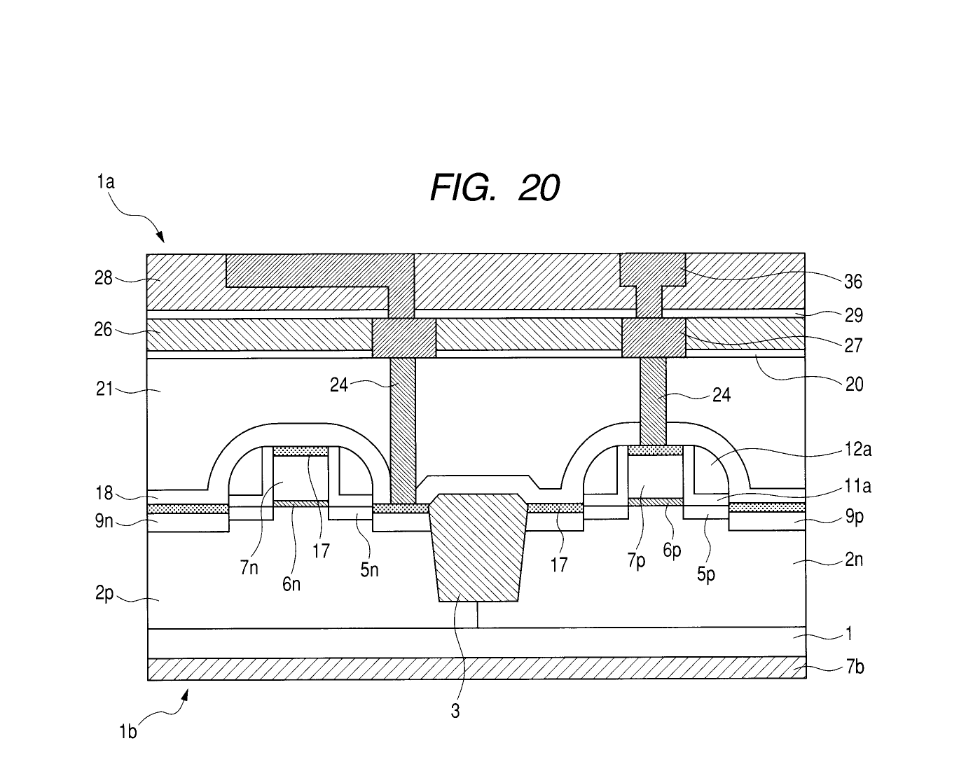

Next, as illustrated in FIG. 20, a barrier metal film, typically including tantalum nitride, of the second embedded wiring layer is formed over portions such as the top surface of the interlayer insulating film 28 of the second embedded wiring layer (i.e., the top surface of the device side 1a of the wafer 1), and inner faces of the trench 35 and via hole 32. Further, a copper seed film is deposited, and subsequent to this, a film of a wiring material containing copper as a principal component is formed typically through electroplating over the portions such as the top surface of the device side 1a of the wafer 1 and the inner faces of the trench 35 and via hole 32.

Further, as illustrated in FIG. 20, the film of wiring material and the barrier metal film each present outside the trench 35 and via hole 32 are removed according typically to metal chemical-mechanical polishing (metal CMP). In this manner, a second embedded wiring 36 is formed. The wiring pitch of the second embedded wiring 36 is, for example, about 300 nm. The thickness of the interlayer insulating films in the first to third embedded wiring layers is, for example, from about 100 to about 200 nm. The wiring pitch of the first to third embedded wirings is, for example, about 300 nm. The thicknesses of the interlayer insulating films and the wiring pitches of fourth and later embedded wiring layers are substantially equal to or larger than these values.

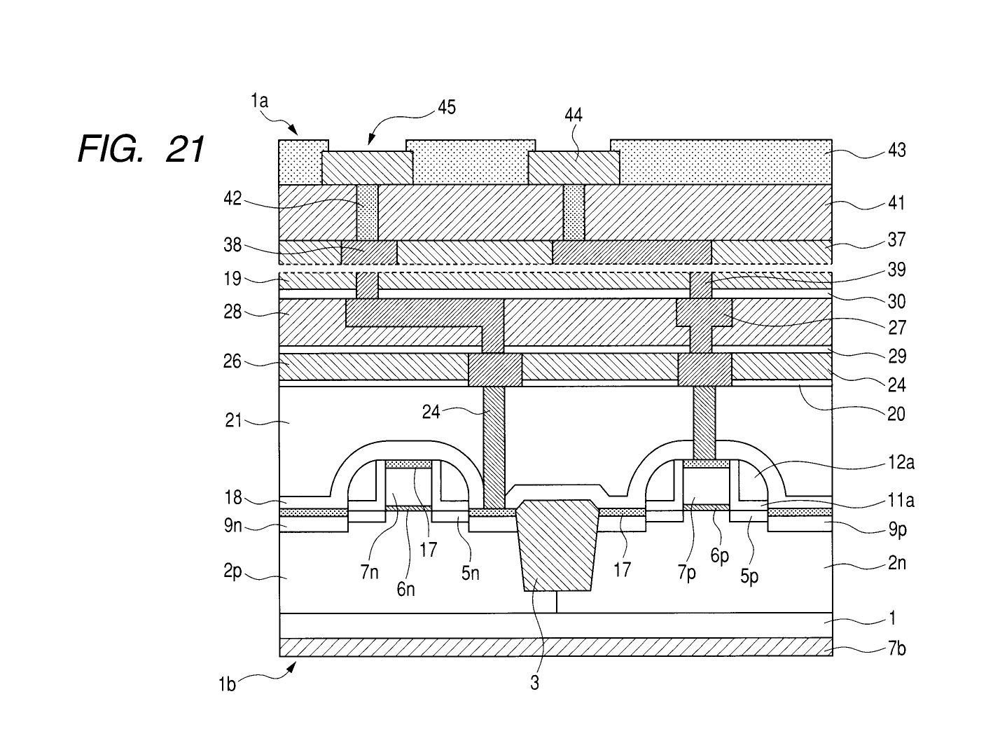

Next, as illustrated in FIG. 21, an interlayer insulating film 19 and an etch stop film 30 for a third embedded wiring layer are sequentially formed; and a third embedded wiring layer 39 having a dual damascene structure is formed typically in the interlayer insulating film 19 and in the etch stop film 30 by the same procedure as in the second embedded wiring layer. This procedure is repeated up to an N-th embedded wiring (N≧3) 38 in an interlayer insulating film (N≧3) 37 of an N-th embedded wiring layer as the uppermost embedded wiring (generally as the fourth layer to the twelfth layer). Thereafter an insulating film 41 to lie under an aluminum-based pad is formed over the interlayer insulating film 37 of the uppermost embedded wiring layer, and tungsten plugs 42 to lie under an aluminum-based pad are embedded so as to penetrate the interlayer insulating film 37.

Further, as illustrated in FIG. 21, an aluminum-based metal film (generally of metal multilayer film structure) is deposited over the insulating film 41 to lie under an aluminum-based pad typically through sputtering. The aluminum-based metal film is patterned through regular lithography to form aluminum-based pad electrodes 44. Subsequently, a final passivation film 43 is formed over the interlayer insulating film 41 and over the aluminum-based pad electrodes 44 typically through plasma CVD. Subsequently, the final passivation film 43 is patterned to form pad openings 45 over the aluminum-based pad electrodes 44.

As is described above and typically in FIG. 1, there is the case where a microprocessing apparatus represented by the microprocessing lithographic apparatus 71 is used in common between one or more microprocessing steps belonging to the embedded wiring process loop 103 in the back end repeating processes 102 and one or more microprocessing steps belonging to the FEOL processes 101 in patterning of each embedded wiring layer. In this case, it is advantageous to carry out a back-side cleaning process as described in Section 2 on a wafer belonging to a back-end process immediately before the introduction into the apparatus. Exemplary microprocessing steps belonging to the embedded wiring process loop 103 include the via hole exposure/development step 123 and the trench exposure/development step 126 (see FIG. 1). Exemplary microprocessing steps belonging to the FEOL processes 101 include the coating/exposure/development step 111 for the patterning of gate electrodes, and the coating/exposure/development step 113 for the formation of contact holes (see FIG. 1). The back-side cleaning processes, however, do not have to be adopted to all the steps in question. To which extent these back-side cleaning processes are adopted is ultimately a matter of cost performance or cost effectiveness. Typically, of wiring layers, the back-side cleaning processes are more advantageously or effectively adopted to wirings of relatively lower layers belonging to local wirings, such as M1 to M5 wiring layers. Such local wirings belong to lower layers than a semiglobal wiring and a global wiring.

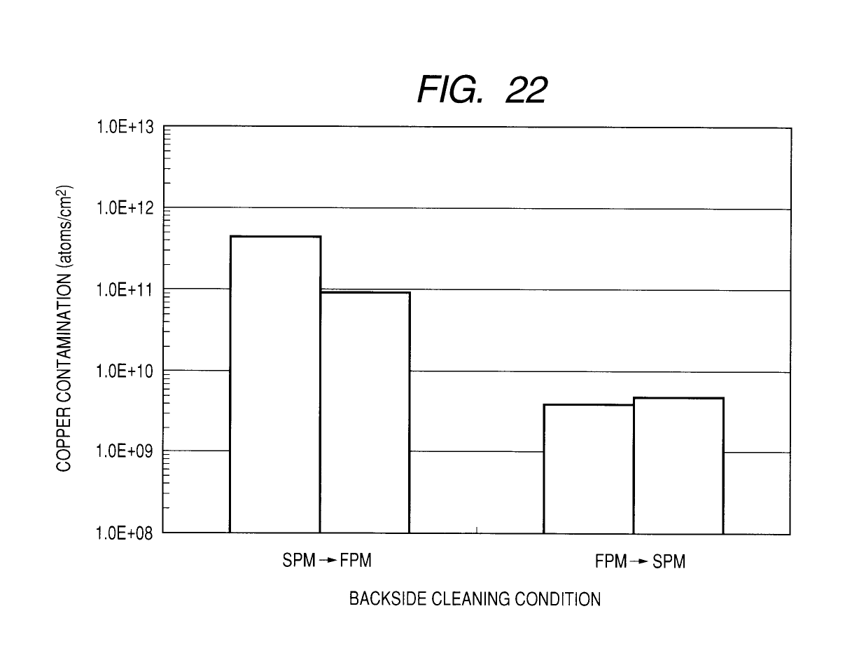

4. Comparison typically between a comparative back-side cleaning process and the back-side cleaning process in the wafer process of the method for fabricating a semiconductor integrated circuit device (as a product including embedded copper wirings) according to an embodiment of the present invention (with reference mainly to FIG. 22)

FIG. 22 is a graph for a comparison in back-side contamination between a back-side cleaning process according to an embodiment of the present invention and another back-side cleaning process as a comparative example. These back-side cleaning processes are adopted to two groups of the back side 1b of the wafer 1 (typically see FIG. 4) which are contaminated with copper substantially to the same degree. The back-side cleaning process according to an embodiment of the present invention is a two-stage cleaning in which FPM cleaning and SPM cleaning are performed in this order. The comparative-example back-side cleaning process is a two-stage cleaning in which SPM cleaning and FPM cleaning are performed in this order. This comparative-example back-side cleaning process is frequently employed when the back side includes a silicon nitride film. Data in FIG. 22 demonstrate that the back-side cleaning process according to an embodiment of the present invention reduces copper contamination as compared to that in the comparative example on the order of two digits.

5. Summary

While the present invention made by the present inventors has been particularly shown and described with reference to preferred embodiments thereof, it will be appreciated that the present invention is not limited thereto. Accordingly, any and all modifications, variations, and changes can be made therein without departing from the spirit and scope of the present invention.

Typically, while the above-mentioned embodiment has been particularly described by taking an embedded copper-based wiring as an example, it will be apparent that the present invention is not limited thereto and can be adopted also to wirings or interconnections of other types, such as embedded silver-based wirings and aluminum-based regular wirings (non-embedded wirings). For example, the present invention can be adopted typically to processing of a thin film such as an aluminum-based wiring (metal wiring) pattern.

When the stress memorization technique (SMT) is adopted, the back side of a wafer becomes a film containing a polysilicon as a main component in the back end repeating processes. The above-mentioned embodiment has been described while focusing around this case. It should be noted, however, the present invention is not limited thereto and is also effective when adopted to the cases where the stress memorization technique (SMT) is not adopted.

What is claimed is:

1. A method for fabricating a semiconductor integrated circuit device, comprising the steps of:
(a) forming a second insulating film over a first insulating film over a device side of a wafer, the second insulating film to be an interlayer insulating film for an embedded wiring;
(b) after the step (a), carrying out a first wet cleaning of a back side of the wafer;
(c) after the step (b), introducing the wafer into a first lithographic apparatus and carrying out a patterning of a first resist film; and
(d) after the step (c), carrying out a first processing of the second insulating film by a first dry etching on the device side of the wafer in the presence of the patterned first resist film,
wherein the step (b) includes the substeps of:
(b1) carrying out the first wet cleaning with a first aqueous solution containing hydrogen fluoride and hydrogen peroxide as principal solute components; and
(b2) after the substep (b1), carrying out the first wet cleaning with a second aqueous solution containing sulfuric acid and hydrogen peroxide as principal solute components.

2. The method for fabricating a semiconductor integrated circuit device according to claim 1, further comprising the steps of:
(e) after the step (d), removing the first resist film;
(f) after the step (e), carrying out a second wet cleaning of the back side of the wafer;
(g) after the step (f), introducing the wafer into the first lithographic apparatus or a second lithographic apparatus and carrying out a patterning of a second resist film;
(h) after the step (g), carrying out a second processing of the second insulating film by a second dry etching on the device side of the wafer in the presence of the patterned second resist film,
wherein the step (f) includes the substeps of:
(f1) carrying out the second wet cleaning with a third aqueous solution containing hydrogen fluoride and hydrogen peroxide as principal solute components; and
(f2) after the substep (f1), carrying out the second wet cleaning with a fourth aqueous solution containing sulfuric acid and hydrogen peroxide as principal solute components.

3. The method for fabricating a semiconductor integrated circuit device according to claim 2, wherein the first processing is via hole etching for the embedded wiring.

4. The method for fabricating a semiconductor integrated circuit device according to claim 3, wherein the second processing is trench etching for the embedded wiring.

5. The method for fabricating a semiconductor integrated circuit device according to claim 4, wherein the embedded wiring is a copper-based dual damascene wiring.

6. The method for fabricating a semiconductor integrated circuit device according to claim 5, wherein each of the first wet cleaning and the second wet cleaning is carried out as a single-wafer processing.

7. The method for fabricating a semiconductor integrated circuit device according to claim 6, wherein the steps (a), (b), (c), (d), (e), (f), (g), and (h) are carried out substantially in the absence of a silicon nitride insulating film over the back side of the wafer.

8. The method for fabricating a semiconductor integrated circuit device according to claim 7, wherein the first aqueous solution is a hydrofluoric acid-hydrogen peroxide mixture (FPM) and the second aqueous solution is a sulfuric acid-hydrogen peroxide mixture (SPM).

9. The method for fabricating a semiconductor integrated circuit device according to claim 8, wherein the third aqueous solution is a hydrofluoric acid-hydrogen peroxide mixture (FPM) and the fourth aqueous solution is a sulfuric acid-hydrogen peroxide mixture (SPM).

10. The method for fabricating a semiconductor integrated circuit device according to claim 9, wherein each of the first aqueous solution and the second aqueous solution is supplied at normal temperatures to the back side of the wafer.

11. The method for fabricating a semiconductor integrated circuit device according to claim 10, wherein each of the third aqueous solution and the fourth aqueous solution is supplied at normal temperatures to the back side of the wafer.

12. The method for fabricating a semiconductor integrated circuit device according to claim 11, wherein the step of forming the second insulating film is carried out as a single-wafer processing.

13. The method for fabricating a semiconductor integrated circuit device according to claim 12,
wherein the semiconductor integrated circuit device includes a metal insulator semiconductor field-effect transistor (MISFET), and
wherein the method for fabricating a semiconductor integrated circuit device further comprises the step of:
(i) before the step (a) and after the step of patterning a gate electrode of the MISFET, carrying out a batchwise wet processing of the wafer with hot phosphoric acid.

14. A method for fabricating a semiconductor integrated circuit device, comprising the steps of:
(a) forming a thin film over an insulating film over a device side of a wafer, the thin film being used for the formation of a metal wiring;
(b) after the step (a), caring out a wet cleaning of a back side of the wafer;
(c) after the step (b), introducing the wafer into a lithographic apparatus and carrying out a patterning of a resist film; and
(d) after the step (c), caring out a processing of the thin film by dry etching of the device side of the wafer in the presence of the patterned resist film,
wherein the step (b) includes the substeps of:
(b1) carrying out the wet cleaning using a first aqueous solution containing hydrogen fluoride and hydrogen peroxide as principal solute components; and
(b2) after the substep (b1), carrying out the wet cleaning using a second aqueous solution containing sulfuric acid and hydrogen peroxide as principal solute components.

15. The method for fabricating a semiconductor integrated circuit device according to claim 14, wherein the first wet cleaning and second wet cleaning are carried out as a single-wafer processing.

16. The method for fabricating a semiconductor integrated circuit device according to claim 15, wherein the steps (a), (b), (c), and (d) are carried out substantially in the absence of a silicon nitride insulating film over the back side of the wafer.

17. The method for fabricating a semiconductor integrated circuit device according to claim 16, wherein the first aqueous solution is a hydrofluoric acid-hydrogen peroxide mixture (FPM) and the second aqueous solution is a sulfuric acid-hydrogen peroxide mixture (SPM).

18. The method for fabricating a semiconductor integrated circuit device according to claim 17, wherein each of the first aqueous solution and the second aqueous solution is supplied at normal temperatures to the back side of the wafer.

19. The method for fabricating a semiconductor integrated circuit device according to claim 18, wherein the step of forming the thin film is carried out as a single-wafer processing.

20. The method for fabricating a semiconductor integrated circuit device according to claim 19,
wherein the semiconductor integrated circuit device includes a metal insulator semiconductor field-effect transistor (MISFET), and
wherein the method for fabricating a semiconductor integrated circuit device further comprises the step of:
(i) before the step (a) and after the step of patterning a gate electrode of the MISFET, carrying out a batchwise wet processing of the wafer with hot phosphoric acid.
